(19) United States
(12) Patent Application Publication
(10) Pub. No.: US 2003/0014716 A1
(43) Pub. Date: Jan. 16, 2003

(54) Universal lossless data compression

(75) Inventor: Meir Ariel, Tel Aviv (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22202, US

(73) Assignee: CUTE Ltd.

(21) Appl. No.: 09/904,590

(22) Filed: Jul. 16, 2001

(51) Int. Cl. H03M 13/03

(52) U.S. Cl. 714/792; 714/793

(57) ABSTRACT

A coset analyzer is used for analyzing time-varying error correction codes in data communications. The time-varying error correction code has cosets, and each coset has a coset leader and a syndrome. The analyzer comprises a coset representation unit for representing a coset of the code as a time-varying error trellis and an error trellis searcher for searching the error trellis. Each member of the coset corresponds to a path through the error trellis. A lossless data sequence compressor and decompressor are also discussed.

### FIELD OF THE INVENTION

The present invention relates to universal lossless data compression, and more particularly but not exclusively to the use of time-varying error trellises for data compression and decompression.

### BACKGROUND OF THE INVENTION

Efficient data transmission and processing systems must fulfill two primary goals: reduction of errors to acceptable limits and efficient use of bandwidth. A variety of error-correction and coding techniques have been developed to reduce transmission errors. These techniques often rely upon increasing the signal space, leading to a rise in required signaling bandwidth. Data compression techniques, on the other hand, are used to reduce signaling bandwidth. In the rapidly developing field of broadband data applications compression techniques are becoming increasingly important.

The concept of universal source coding has been the subject of much research since the early seventies (e.g. L. D. Davisson, “Comments on Sequence time coding for data compression',” in Proc. IEEE (Lett.), vol. 54, p. 2010, December 1966, L. D. Davisson, “Universal noiseless coding”, IEEE Transactions on Information Theory, vol. IT-19, pp. 783-795, November 1973, and J. Ziv, “Coding of sources with unknown statistics-Part I: Probability of encoding error”, IEEE Transactions on Information Theory, vol. IT-18, pp. 384-394, May 1972, and J. Rissanen “A universal data compression system”, IEEE Transactions on Information Theory, vol. 29, pp. 656-664, September 1983). Algorithms for universal lossless compression of stationary sources achieve asymptotically optimum mean per symbol length without known a priori source probabilities (e.g., T. J. Lynch, “Sequence time encoding for data compression”, in Proceedings of the IEEE (Lett.), vol. 54, pp. 1490-1491, October 1966, J. P. M. Schalkwijk, “An algorithm for source encoding”, IEEE Transactions on Information Theory, vol. IT-18, pp. 395-399, May 1972, T. M. Cover, “Enumerative source encoding”, IEEE Transactions on Information Theory, vol. IT-19, pp. 73-77, January 1973, J. Ziv and A. Lempel, “A universal algorithm for sequential data compression”, IEEE Transactions on Information Theory, vol. IT-23, pp. 337-343, May 1977, and. J. Ziv and A. Lempel, “Compression of individual sequences via variable-rate coding”, IEEE Transactions on Information Theory, vol. IT-24, pp. 530-536, September 1978). Contents of the above articles are hereby incorporated by reference.

Convolutional coding is a well-established coding technique. A convolutional code is generated by passing the data sequence through a linear finite-state shift register and generating the output digits as linear combinations of the elements in the shift register. Consider a memoryless source emitting binary sequences of length N with Prob(1)=p and Prob(0)=1−p, where p is unknown and allowed to change between 0 and ½ throughout the sequence. For simplicity of the following explanation discusses memoryless sources. The same principles, however, apply to other types of information sources. Denote by I the index set {1, 2, . . . , b}. Let F={C1, C2, . . . , Cb} be a family of b binary convolutional codes. Each member of F has parameters (ni, ki) and rate ki/ni, where i belongs to I. The set F is selected such that its members have rates ranging between 0 and 1. A convolutional code Ci can be specified by a polynomial parity check matrix Hi(D) (the matrix Hi(D) is a generator matrix to the code dual to Ci). Assume that all the matrices Hi(D) are canonical and have the same state space. Thus all the trellis diagrams representing the codes belonging to F have the same number of states. Denoting by m(i) the maximum degree among the polynomials of Hi(D), Hi(D) can be decomposed as follows:

Hᵢ(D)=H_{i,0}+H_{i,1}D+ . . . +H_{i,m(i)}D^{m(i)}

where the H_{i,j} are matrices over GF(2) (i.e., binary) with dimensions (nᵢ−kᵢ)×nᵢ. A convolutional code Cᵢ can now be specified through its scalar parity-check matrix Hᵢ as follows:

$${H}_{i} = [ \begin{matrix} {H}_{i , 0} & & & \\ {H}_{i , 1} & {H}_{i , 0} & & \\ {H}_{i , 2} & {H}_{i , 1} & & {H}_{i , 0} \\ ⋮ & {H}_{i , 2} & & {H}_{i , 1} \\ {H}_{i , m ( i )} & ⋮ & ⋯ & {H}_{i , 2} \\ & {H}_{i , m ( i )} & & ⋮ \\ & & & {H}_{i , m ( i )}\end{matrix} ] .$$

Similarly, a time-varying convolutional code C may be defined via its time-varying scalar parity-check matrix H as follows:

$$H = [ \begin{matrix} {H}_{i ( 1 ) , 0} & & & \\ {H}_{i ( 1 ) , 1} & {H}_{i ( 2 ) , 0} & & \\ {H}_{i ( 1 ) , 2} & {H}_{i ( 2 ) , 1} & & {H}_{i ( L ) , 0} \\ ⋮ & {H}_{i ( 2 ) , 2} & & {H}_{i ( L ) , 1} \\ {H}_{i ( 1 ) , m ( i ( 1 ) )} & ⋮ & ⋯ & {H}_{i ( L ) , 2} \\ & {H}_{i ( 2 ) , m ( i ( 2 ) )} & & ⋮ \\ & & & {H}_{i ( L ) , m ( i ( L ) )}\end{matrix} ]$$

In the above matrix H, index i(l) belongs to I, and m(i(l)) is the maximum degree among the polynomials of the parity-check matrix Hᵢ₍ₗ₎(D) for the code Cᵢ₍ₗ₎. A binary matrix in H, such as H_{i(l),m(i(l))}, has dimensions (nᵢ₍ₗ₎−kᵢ₍ₗ₎₎×nᵢ₍ₗ₎. The sequence length N is equal to the number of columns of H, and is given by:

N=Σ_{l=1 to L}nᵢ₍ₗ₎.

Note that i(1) is not necessarily equal to 1 and that l≠q does not necessarily imply that i(l)≠i(q). When constructing a code C, a member of F can be drawn more than once.

In both the time-invariant and the time-varying convolutional code, the parity check matrix can be used to detect errors in a received encoded sequence. In hard-decision decoding, the received signal, R, is multiplied by the transpose of the parity check matrix H to form a syndrome vector, s, defined by:

s=YH^{t}

Each syndrome vector s is associated with a set of received vectors. The set of received vectors is denoted a coset.

Certain lossy compression techniques make use of the parity check matrix H. Denoting by M the total number of rows of H, then for any given N-tuple x=(x₁, x₂, . . . , x_{N}) obtained at the output of the memoryless source an encoded M-tuple y=(y₁, y₂, . . . , y_{M}) is calculated as follows:

y=xH^{t}

where t stands for transposition. Note that y is the syndrome sequence associated with the coset of C to which x belongs. For a convolutional code of rate k/n<1, M is less than N. Using y to represent the data vector x compresses the N-tuple data into an M-tuple signal. Encoded vector y indicates that x is a member of the coset associated with y, but does not specify a particular member of the coset. Since x cannot be uniquely reconstructed from y, signal information is lost. Suitable uses for the above techniques are thus extremely limited.

There is a need for a lossless compression technique that enables efficient data signaling. A universal compression technique that is independent of source statistics would be widely applicable to a wide variety of signals.

### SUMMARY OF THE INVENTION

According to a first aspect of the present invention there is thus provided a coset analyzer for use with time-varying error correction codes in data communications, the time-varying error correction code having cosets, each coset having a coset leader and syndrome. The analyzer has a coset representation unit for representing a coset of the code as a time-varying error trellis, the error trellis having a path corresponding to each member of the coset, and an error trellis searcher for searching the error trellis. In a preferred embodiment the coset analyzer is operable to determine if a data sequence has a coset leader of the coset. In another preferred embodiment the coset analyzer determines if a data sequence has a member of the coset. In an additional embodiment of the coset analyzer, the error trellis searcher has weight determination functionality to determine a minimum Hamming weight path through the error trellis thereby to identify the coset leader. In a further embodiment, the time-varying error correction code is a convolutional code. In another preferred embodiment the coset representation unit is forms the error trellis by concatenating a sequence of error trellis modules. The error trellis modules are selectable from a predetermined set of modules. In an alternate embodiment, the coset representation unit is operable to determine the sequence of error trellis modules from the convolutional code and from a syndrome sequence associated with the coset. In a preferred embodiment of the coset analyzer, the error trellis searcher is operable to find the coset leader by performing a Viterbi algorithm search of the error trellis to detect a minimum Hamming weight path through the error trellis. In an embodiment, the coset analysis unit further has a sequence comparator associated with the error trellis searcher, and the sequence comparator is operable to perform a symbol by symbol comparison of an input sequence with the coset leader thereby to determine a symbol at which the input sequence and the coset leader diverge.

According to a second aspect of the present invention there is thus provided a lossless data sequence compressor, for compressing an input data sequence into a compressed sequence without loss of information utilizing a dynamically-generated compression code. The compression code is a time-varying error correction code having cosets, each coset having a coset leader and syndrome. The compressor comprises a sequence producer, and an information sequence generator. The sequence producer produces a compressed sequence having the syndrome of a coset of the compression code, such that the input sequence has a coset leader of the coset. The information sequence generator generates an information sequence indicative of the compression code, and affixes the information sequence to the compressed sequence thereby to form an output sequence.

In a preferred embodiment the sequence producer is operable iteratively to produce the compressed sequence until a termination condition is reached, thereby producing a concluding compressed sequence and compression code. In another embodiment the sequence producer has a code generator for producing successive iterations of the compression code. In an additional embodiment the sequence producer further has an input segment encoder for selecting a segment of the input data sequence, and encoding the segment into a compressed segment by means of a current iteration of the dynamically generated compression code. In a preferred embodiment the segment of the input data sequence has an entire input data sequence.

In another embodiment the dynamically generated compression code has a time-varying convolutional code. In a preferred embodiment the input segment encoder is operable to encode the input data segment by multiplying the input data segment by a transpose of a parity check matrix of the time-varying convolutional code. In an additional preferred embodiment the code generator is operable to construct a compression code as a sequence of sub-codes. In an embodiment the code generator is operable to construct the compression code by dynamically selecting a sequence of sub-codes from a predetermined set of sub-codes. In a preferred embodiment the sub-codes are convolutional codes.

In a preferred embodiment the input segment encoder has a segment divider for dividing the input data sequence into variable length sub-segments and a segment compressor. The segment compressor is for compressing each of the sub-segments with an associated sub-code dynamically selected by the code generator for the sub-segment.

In a preferred embodiment of the segment compressor, the segment compressor has a transposer for transposing a parity check matrix of a sub-code associated with the sub-segment to form a transposed parity check matrix and a multiplier for encoding each of the sub-segments by multiplying the sub-segment by a transposed parity check matrix of the associated sub-code. A preferred embodiment of the input segment encoder has a sub-segment length adjustment. In another preferred embodiment the code generator has code adjustment functionality for dynamically adjusting the compression code in accordance with the sub-segment length.

In an additional preferred embodiment the input segment encoder and the code generator are jointly operable to dynamically adjust the sub-segments and the sequence of sub-codes to fulfill at least one predetermined coding constraint. In a preferred embodiment, the input segment encoder is operable to restrict input sub-segment length to less than a predetermined length. Alternatively, the encoder is operable to restrict input sub-segment length to less than a predetermined length if a coding rate of the associated sub-code is less than a predetermined coding rate.

In a preferred embodiment the sequence producer further has a coset analyzer operable to identify a coset leader of a coset of the compression code and to compare the coset leader to the input data sequence, wherein the coset is determined by the compressed segment and the compression code. In a preferred embodiment the coset analyzer has an error trellis generator that represents the coset as an error trellis. The error trellis has a path corresponding to each member of the coset. In a preferred embodiment the error trellis generator is operable to generate the trellis as a concatenated sequence of error trellis modules dynamically selected from a predetermined set of error trellis modules. In an additional embodiment the error trellis generator is operable to determine the structure of the error trellis from the compressed segment and the compression code. In a preferred embodiment the error trellis generator determines the structure of the error trellis from the compressed segment and from the sequence of sub-codes.

In a preferred embodiment the coset analyzer further has an error trellis searcher operable to search the error trellis for a coset leader. In another preferred embodiment the error trellis searcher is operable to identify the coset leader by performing a search of the error trellis to detect a minimum Hamming weight path through the error trellis. In another embodiment the search is a Viterbi algorithm search. In a preferred embodiment the coset analyzer further has a sequence comparator operable to perform a symbol by symbol comparison of the input segment with the coset leader, thereby to determine a symbol at which the input segment and the coset leader diverge.

In a preferred embodiment the input segment encoder and the code generator are jointly operable to dynamically adjust input data segment length and the compression code additionally based on information provided by the coset analyzer. In another preferred embodiment of the information sequence generator, the information sequence includes an identification of the compression code utilized to generate the compressed sequence.

According to a third aspect of the present invention there is thus provided a lossless data sequence decompressor for decompressing a compressed sequence into an output sequence without loss of information, wherein the compressed sequence comprises a syndrome of a coset of a time-varying error correction code and an information sequence indicative of the time-varying error correction code. The decompressor has an information sequence separator, operable to separate the compressed sequence into the syndrome and the information sequence, and an expander operable to decompress the compressed sequence into the output sequence such that the output sequence equals a coset leader of the coset. In a preferred embodiment the expander further comprises an error trellis regenerator operable to represent the coset as a time-varying error trellis, the error trellis comprising a path corresponding to each member of the coset. In a preferred embodiment the error trellis regenerator is operable to generate the error trellis as a concatenated sequence of error trellis modules. Each of the modules is dynamically selectable from a predetermined set of modules. In another preferred embodiment the error trellis regenerator is operable to determine the sequence of error trellis modules from the syndrome and from the information sequence. In an additional embodiment the expander further comprises an error trellis searcher operable to search the error trellis for a coset leader. In a preferred embodiment the search is performed as a Viterbi algorithm search of the error trellis to detect a minimum Hamming weight path through the error trellis.

According to a fourth aspect of the present invention there is thus provided a communication device having a first signal converter for converting a first data sequence into a first output sequence without loss of information utilizing a compression code. The compression code comprises a time-varying error correction code having cosets, each coset having a coset leader and syndrome. The first signal converter comprises a sequence producer and an information sequence generator. The sequence producer produces a compressed sequence comprising the syndrome of a coset of the compression correction code, such that the first data sequence comprises a coset leader of the coset. The information sequence generator generates an information sequence indicative of the compression code, and affixes the information sequence to the compressed sequence to form a first output sequence. In a preferred embodiment the sequence producer is operable iteratively to produce the compressed sequence until a termination condition is reached, thereby producing a concluding compressed sequence and compression code. In another preferred embodiment the sequence producer comprises a code generator for producing successive iterations of the compression code. In a preferred embodiment the sequence producer further comprises an input segment encoder for selecting a segment of the input data sequence, and encoding the segment into a compressed segment by means of a current iteration of the dynamically generated compression code. In a preferred embodiment the segment of the input data sequence comprises an entire input data sequence. In a preferred embodiment the sequence producer further comprises a coset analyzer operable to identify a coset leader of a coset of the compression code, wherein the coset is determined by the compressed segment and the compression code.

In a preferred embodiment the coset analyzer has an error trellis generator for forming the error trellis as a concatenated sequence of error trellis modules dynamically selectable from a predetermined set of modules. In a preferred embodiment the error trellis generator is operable to determine the sequence of error trellis modules from the syndrome and from the information sequence. In another preferred embodiment the coset analyzer further has an error trellis searcher operable to search the error trellis for a coset leader. In an embodiment the coset analyzer further has a comparator operable to perform a symbol by symbol comparison of the input segment with the coset leader, thereby to determine a symbol at which the first data segment and the coset leader diverge. In another preferred embodiment the information sequence generator is operable to include in the information sequence an identification of the compression code utilized to generate the compressed sequence. In an additonal embodiment the error trellis searcher identifies the coset leader by performing a Viterbi algorithm search of the error trellis to determine a minimum Hamming weight path through the error trellis.

In a preferred embodiment the communication device further comprises a second signal converter for converting a second data sequence into a decompressed sequence without loss of information. The second data sequence has a syndrome of a coset of a time-varying error correction code and an information sequence indicative of the time-varying error correction code. The second signal converter comprises an information sequence separator, operable to separate the second data sequence into the syndrome and the information sequence and an expander operable to expand the compressed sequence into the decompressed sequence such that the decompressed sequence equals a coset leader of the coset. In a preferred embodiment the expander comprises an error trellis regenerator operable to represent the coset as a dynamically generated error trellis. The error trellis has a path corresponding to each member of the coset.

In an embodiment the error trellis regenerator is operable to construct the error trellis as a concatenated sequence of error trellis modules, the modules being dynamically selectable from a predetermined set of modules. In another embodiment the error trellis regenerator is operable to determine the sequence of error trellis modules from the syndrome and the information sequence. In a preferred embodiment the expander further comprises an error trellis searcher operable to search the error trellis for a coset leader. In an additional preferred embodiment the error trellis searcher performs the search as a Viterbi algorithm search of the error trellis thereby to detect a minimum Hamming weight path through the error trellis.

In a preferred embodiment the communication device is one of a group of devices. The group comprises: a router, a data switch, a data hub, a terminal for wireless communications, a terminal for wire communications, a personal computer, a cellular telephone handset, a mobile communication handset, and a personal digital assistant.

According to a fifth aspect of the present invention there is thus provided a method for analyzing a coset of a time-varying error correction code for data communications, the time-varying error correction code having cosets, each coset having a coset leader and syndrome. The method comprises the steps of: representing a coset of the code as a time-varying error trellis, and analyzing the coset to determine at least one property thereof. In a preferred embodiment determining a property of the coset comprises identifying a coset leader of the coset. In a preferred embodiment identifying a coset leader of the coset comprises searching the error trellis for a minimum Hamming weight path through the error trellis. Alternately, determining a property of the coset comprises determining whether a data sequence comprises a member of the coset.

In a preferred embodiment the code comprises a convolutional code. In an additonal embodiment, representing the error trellis comprises concatenating a sequence of error trellis modules. The modules are selected from a predetermined set of modules. In another preferred embodiment the sequence of error trellis modules is determined from the time-varying error correction code and from a syndrome sequence associated with the coset of the code.

According to a sixth aspect of the present invention there is thus provided a method for compressing an input data sequence into a compressed sequence without loss of information, having the steps of: inputting an input data sequence, generating a time-varying error correction code having the input data sequence as a coset leader of a coset of the code, determining the syndrome of the coset, and forming an output sequence by affixing an information sequence indicative of the error-correction code to the syndrome. In a preferred embodiment the step of generating a time-varying error correction code comprises dynamically selecting a sequence of sub-codes from a predetermined set of sub-codes. In another preferred embodiment the sequence of sub-codes is determined from the input data sequence.

According to a seventh aspect of the present invention there is thus provided a method for compressing an input data sequence into a compressed sequence without loss of information, comprising the steps of: inputting an input data sequence, constructing an initial time-varying error correction code comprises cosets, determining a parity check matrix for the code, selecting a segment of the input data sequence, and performing an compression cycle to compress the segment of the data sequence. The compression cycle is performed by: multiplying the segment of the input data sequence with a transpose of the parity check matrix to obtain a syndrome sequence, representing a coset associated by the code with the syndrome sequence as an error trellis, determining a coset leader of the coset, and comparing the coset leader to the input sequence. If the coset leader and the segment of the input sequence are not identical, continuing the compression by: updating the time-varying error correction code, determining a parity check matrix for the code, updating the segment of the input data sequence, and repeating the compression cycle to compress the segment of the input data sequence. If the coset leader and the segment of input sequence are identical, continuing the compression by comparing the lengths of the coset leader and the input sequence. If the lengths of the coset leader and the input sequence are not equal, the compression continues by: updating the time-varying error correction code, determining a parity check matrix for the code, extending the segment of the input data sequence, and repeating the compression cycle to compress the segment of the input data sequence. If the lengths of the coset leader and the input sequence are equal, the compression ends by: forming an information sequence indicative of the time-varying error correction code, forming a compressed sequence by affixing the information sequence to the syndrome sequence, and outputting the compressed sequence. In a preferred embodiment the segment of the input data sequence comprises the entire input data sequence.

In a preferred embodiment the time-varying error correction code comprises a time-varying convolutional code. In a further embodiment the convolutional code comprises a sequence of convolutional sub-codes, and the sub-codes are selected from a predetermined set of sub-codes. In a preferred embodiment constructing an initial time-varying error correction code comprises dynamically selecting an initial sequence of sub-codes from a predetermined set of sub-codes. In another embodiment updating the time-varying error correction code having cosets comprises dynamically reselecting the sequence of sub-codes.

In a preferred embodiment multiplying the segment of the input data sequence with a transpose of the parity check matrix comprises the steps of: dividing the input data sequence into variable length sub-segments, associating a sub-code with each of the sub-segments, and multiplying the input data segment by a transpose of a parity check matrix of the sub-code associated with the sub-segment. One embodiment further comprises ensuring that the length of each of the sub-segments does not exceed a predetermined size. In another embodiment, determining a coset leader of the coset comprises searching the error trellis for a minimum Hamming weight path through the error trellis. For example, the search is performed as a Viterbi algorithm search.

In a preferred embodiment representing a coset associated by the code with the syndrome sequence as an error trellis comprises: determining a sequence of error trellis modules selected from a predetermined set of modules, and forming the error trellis by concatenating the error trellis modules according to the determined sequence. The sequence of error trellis modules is determined from the time-varying error correction code and from the syndrome sequence.

According to an eighth aspect of the present invention there is thus provided a method for compressing an input data sequence into a compressed sequence without loss of information, by performing the steps of: inputting an input data sequence, selecting an initial compression code having cosets, selecting a segment of the input data sequence, and performing a compression cycle to compress the segment of the data sequence. The compression cycle is performed by: encoding the segment of the input data sequence with the compression code to form an encoded sequence, and analyzing a coset associated with the compression code by the compressed sequence to determine if the encoded sequence equals a coset leader of the coset. If the segment of the input data sequence does not equal the coset leader, continuing the compression by: reselecting a compression code, reselecting a segment of the data sequence, and repeating the compression cycle. If the segment of the input data sequence equals the coset leader, the compression is continued by comparing the lengths of the coset leader and the input sequence. If the lengths of the coset leader and the input sequence are not equal, the compression is continued by: extending the compression code, extending the segment of the data sequence, and repeating the compression cycle. If the lengths of the coset leader and the input sequence are equal, the compression is ended by: forming an information sequence indicative of the compression code, forming a compressed sequence by affixing the information sequence to the encoded sequence, and outputting the compressed sequence.

In a preferred embodiment, analyzing a coset associated with the compression code comprises: representing the coset as an error trellis, searching the error trellis to determine a coset leader, and comparing the coset leader with the encoded sequence. In an additional embodiment, the error trellis is searched by performing a Viterbi algorithm search to identify a minimum Hamming weight path through the error trellis. In a preferred embodiment representing the coset as an error trellis comprises: determining a sequence of error trellis modules from the compression code and from the encoded sequence, wherein the modules are selected from a predetermined set of modules, and concatenating the error trellis modules according to the sequence.

In a preferred embodiment the compression code comprises a time-varying error correction code. In a further embodiment the time-varying error correction code comprises a time-varying convolutional code. In an additional embodiment, encoding the segment of the input data sequence comprises multiplying the segment by a transpose of a parity check matrix of the convolutional code.

According to a ninth aspect of the present invention there is thus provided a method for decompressing a compressed sequence without loss of information by: inputting the compressed sequence, separating the compressed sequence into a syndrome and an information sequence, analyzing a coset associated with the syndrome to determine a coset leader for the coset, and outputting the coset leader. In a preferred embodiment analyzing a coset associated with the syndrome to determine a coset leader for the coset comprises: representing the coset as a time-varying error trellis, and searching the trellis to identify a Hamming weight path through the error trellis.

In a preferred embodiment representing the coset as a time-varying error trellis comprises: determining a sequence of error trellis modules from the information sequence and the syndrome, wherein the modules are selected from a predetermined set of modules, and concatenating the error trellis modules according to the sequence. In a further embodiment, searching the trellis to identify a minimum Hamming weight path comprises performing a Viterbi algorithm search to identify the path.

According to a tenth aspect of the present invention there is thus provided a method for communicating data by transmitting and receiving data sequences. A first data sequence is transmitted by converting the first data sequence into a compressed output data sequence without loss of information and transmitting the compressed sequence. The compressed sequence is transmitted by performing the steps of: inputting the first data sequence, generating a time-varying error correction code comprising the first data sequence as a coset leader of a coset of the code, determining the syndrome of the coset, forming an information sequence indicative of the time-varying error-correction code, forming a compressed sequence by affixing the information sequence to the syndrome, and transmitting the compressed sequence. A second data sequence is received by: receiving the second data sequence and converting the second data sequence into a decompressed sequence without loss of information. The second data sequence is converted into a decompressed sequence without loss of information by performing the steps of: receiving the second data sequence, separating the second data sequence into a syndrome and an information sequence, representing a coset associated with the syndrome as a time-varying error trellis, analyzing the error trellis to determine a coset leader for the coset, and setting the decompressed sequence equal to the coset leader.

According to an eleventh aspect of the present invention there is thus provided a coset analyzer for use with trellis codes in data communications, the trellis code having cosets, each coset having a coset leader and syndrome. The analyzer comprises: a coset representation unit for representing a coset of the code as a time-varying error trellis, and an error trellis searcher for searching the error trellis. The error trellis has a path corresponding to each member of the coset. In a preferred embodiment the trellis code comprises a time-varying error correction code. In a further embodiment the time-varying error correction code comprises a convolutional code. Alternately, the time-varying error correction code comprises a block code.

According to a twelfth aspect of the present invention there is thus provided a method for analyzing a coset of a trellis code for data communications, by performing the steps of: representing a coset of the code as a time-varying error trellis, and analyzing the coset to determine at least one property thereof. The trellis code has cosets, and each coset has a coset leader and syndrome. In a preferred embodiment the trellis code comprises a time-varying error correction code. In a further embodiment the time-varying error correction code comprises a convolutional code. Alternately, the time-varying error correction code comprises a block code.

### BRIEF DESCRIPTION OF THE DRAWINGS

For a better understanding of the invention and to show how the same may be carried into effect, reference will now be made, purely by way of example, to the accompanying drawings, in which:

FIGS. 1a and 1b show a simplified block diagram of a data sequence compressor and decompressor respectively.

FIG. 2 shows an example of four error trellis modules of a convolutional code.

FIG. 3 shows a simplified block diagram of a Coset Analysis Unit.

FIG. 4 shows a simplified block diagram of a lossless data sequence compressor.

FIG. 5 shows a simplified block diagram of a lossless data sequence compressor.

FIG. 6 shows a simplified block diagram of a segment encoder.

FIG. 7 shows a simplified block diagram of a lossless data sequence decompressor.

FIG. 8 shows a simplified block diagram of a communication device.

FIG. 9 is a simplified flow chart of a method for analyzing a coset.

FIG. 10 is a simplified flow chart of a method for compressing an input sequence.

FIG. 11 is a simplified flow chart of an additional method for compressing an input sequence.

FIG. 12 is a simplified flow chart of a method for multiplying an input sequence by the transpose of a parity check matrix to form a syndrome sequence.

FIG. 13 is a simplified flow chart of a method for representing a coset as an error trellis.

FIG. 14 is a simplified flow chart of an additional method for compressing an input sequence.

FIG. 15 is a simplified flow chart of a method for analyzing a coset.

FIG. 16 is a simplified flow chart of a method for decompressing an input sequence.

FIG. 17 is a simplified flow chart of a method for analyzing a coset.

### DESCRIPTION OF THE PREFERRED EMBODIMENTS

Currently available data sequence compression and decompression techniques provide either lossy compression in which the data sequence recovered may differ from the original sequence, or relatively complex and costly lossless compression. There is a need for a simple and efficient lossless compression/decompression technique with reduced overall processing requirements. The embodiments described below utilize error trellis analysis methods to provide such a solution. The primary encoding step is the construction of and search through an error-trellis representing a coset of a time-varying convolutional code C. Code C itself is unknown in advance, and is created during compression from predetermined building blocks.

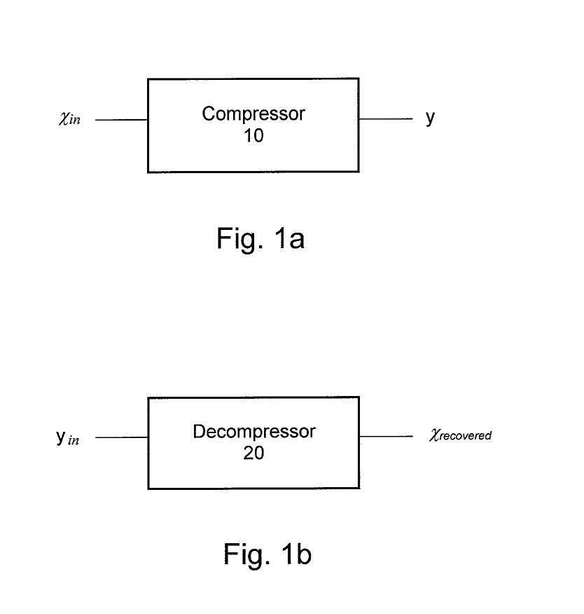

Reference is now made to FIGS. 1a and 1b, which show a simplified block diagram of a data sequence compressor and decompressor respectively. Compressor 10 converts data sequence x into a compressed sequence y. Decompressor 20 decompresses a compressed sequence y into a sequence x′. If:

x′=x

for all values of the input sequence x, the compression is lossless. The compressed signal generally undergoes further processing and transmission through a data communication channel prior to decompression.

In the lossy compression technique described in the background section, an input sequence x is compressed into a shorter sequence y, where y is the syndrome of a coset of a given error correction code C. Compressed sequence y, however, does not provide any information regarding which member of the given coset served as the input sequence. In order for sequence x to be uniquely determined from the compressed sequence, additional information must be provided during compression.

In the preferred embodiments described below the information necessary to ensure lossless compression is added by ensuring that the following constraint, referred to hereafter as the Syndrome Constraint, is satisfied:

### Syndrome Constraint: The Source Emits Only Coset Leaders.

A coset leader is the member of the coset with the minimum Hamming weight among the members of a coset of a code. The Syndrome Constraint specifies a single member of a given coset as the uncompressed input sequence. When the Syndrome Constraint is satisfied, given a known code, sequence x is accurately recoverable from a compressed sequence y by selecting the coset leader of the coset associated with syndrome y.

The Syndrome Constraint may be checked by error trellis analysis. Error trellis analysis represents a coset of a code as a time-varying error trellis. Each member of the coset forms a path through the trellis. That is, for a given coset v+C of a code C, where v is a sequence belonging to v+C, an error-trellis is a directed graph that represents all sequences belonging to v+C. The error trellis is analyzed to determine coset properties. Time-varying error trellises for convolutional codes are known in the art. Construction of time-varying error-trellises is based on a technique for constructing minimal error-trellises presented in the paper “Error-trellises for convolutional codes-Part I: Construction,” IEEE Transactions on Communications vol.46, pp. 1592-1601, December 1998” by Ariel and Snyders, contents of which are hereby incorporated by reference.

For data coding, a maximum-likelihood decoding approach can be based on the concept of error-trellis. Denote by c a codeword in C, and suppose that c is transmitted through an additive white Gaussian noise (AWGN) channel. A binary sequence u is obtained by applying symbol-by-symbol detection to the sequence received at the output of the channel. Associate a binary error sequence e with each codeword c in C, such that:

u=c+e

where the addition is over GF(2). The syndrome y=Hu^{t} then satisfies:

y=H(c+e)^{t}=0+He=He^{t},

since by definition Hc^{t} equals zero for any legitimate code word.

Under maximum-likelihood hard-decision decoding, the most likely codeword c_{ML} is given by c_{ML}=u−e_{LW}, where e_{LW} is the least-weight error-vector within the coset u+C. In other words, e_{LW} is the coset leader of the coset given by y. If y=0, then c_{ML}=u. Otherwise, a search through coset u+C is necessary to identify e_{LW}. An error-trellis can be used to represent coset u+C, and to implement the search for the coset leader.

Error trellis construction is based upon a set of error-trellis modules for the given code C. An error-trellis module is a four-tuple (A,B,D,S), where A stands for the set of source states, B stands for the set of sink states, D is the set of branches connecting the members of A to those of B, and S is the value of the associated syndrome segment. The set of branches D carries the bits that form the sequence. The set of sink states B is often the same as the set of source states A.

The error trellis modules can be connected to form an error-trellis or time-varying error trellis if their state spaces coincide. That is, module i can be connected to Module i−1 if A(i)=B(i−1), where A(i) denotes the source states of the i-th module, and B(i−1) denotes the source states of the (i−1)-th module. For any given coset of code C the error trellis modules can be assembled into a trellis that represents all members of the coset as paths through the trellis.

The first step in the construction of the error-trellis is to partition y into segments sᵢ of fixed length d. The construction is modular and produces a unique state space irrespective of the position of the trellis section. Thus the structure of a trellis section is independent of the paths that connect the root of the trellis to that section. The entire description of any section of the error-trellis at time i depends solely on the value of the associated segment sᵢ of the syndrome, and not on previous syndrome segments. Since a binary d-tuple assumes only 2^{d} values, a set of 2^{d} trellis modules is sufficient for the construction of any error-trellis for any coset of C. Modularity allows error-trellises to be composed dynamically from the predetermined modules according to the value of segments along the syndrome, which sharply reduces the storage complexity.

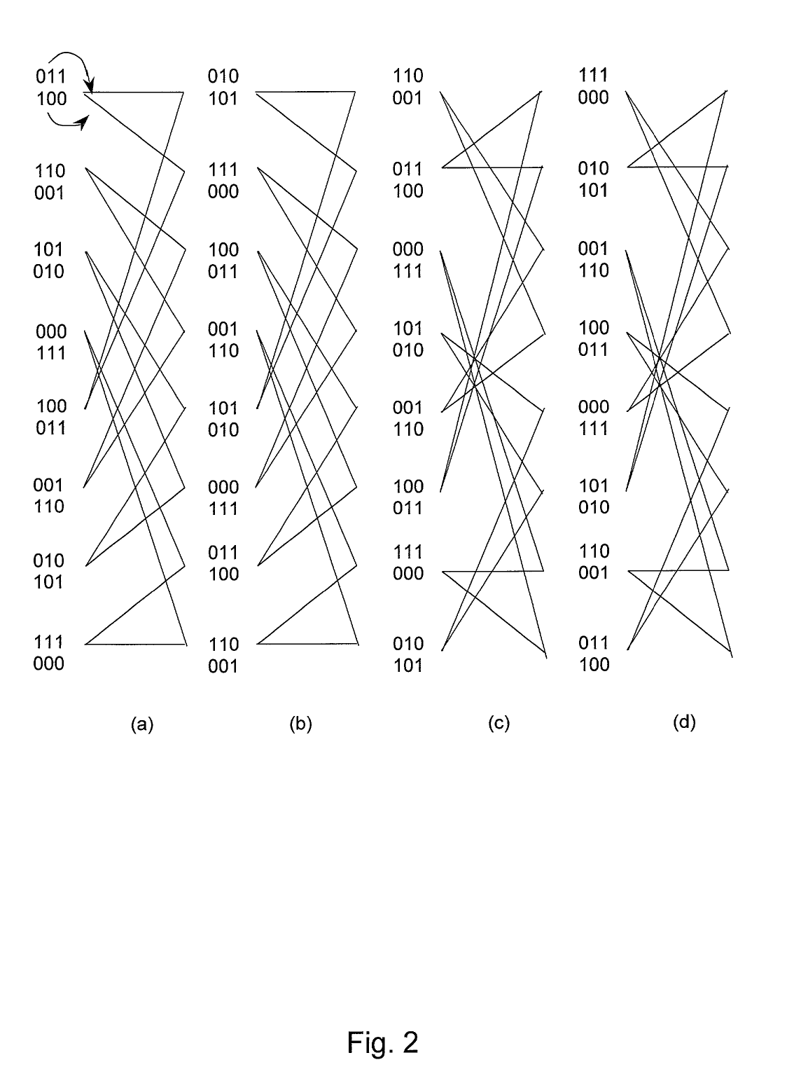

Reference is now made to FIG. 2, which shows an example of four error trellis modules of the convolutional code given below. A rate ⅓ 8-state lowing polynomial parity-check matrix:

$$H ( D ) = [ \begin{matrix}1 + D & D & 1 \\ 1 + {D}^{2} + {D}^{3} & 1 + D + {D}^{2} + {D}^{3} & 0\end{matrix} ] ,$$

The above code has a corresponding scalar parity-check matrix:

$$H = [ \begin{matrix}101 & & & \\ 110 & 101 & & \\ 110 & 110 & & \\ 010 & 110 & & \\ 000 & 010 & & 101 \\ 110 & 000 & … & 110 \\ 000 & 110 & & 110 \\ 110 & 000 & & 010 \\ & 110 & & 000 \\ & & & 110 \\ & & & 000 \\ & & & 110\end{matrix} ] .$$

Any coset of the above code may be represented by an error trellis constructed from the set of four error trellis modules shown in FIG. 2, where each module corresponds to one of the four values of a 2-bit segment sᵢ of a syndrome. The set is sufficient to construct error-trellises for any coset of the given code.

A discussion of the construction, structure and decoding of error-trellises is presented in the papers by Meir Ariel and Jakov Snyders, “Soft syndrome decoding of binary convolutional codes,” IEEE Transactions on Communications, vol.43, pp. 288-297, February 1995, “Error-trellises for convolutional codes-Part I: Construction,” IEEE Transactions on Communications, vol.46, pp. 1592-1601, December 1998, and “Error-trellises for convolutional codes-Part II: Decoding methods,” IEEE Transactions on Communications, vol.47, pp. 1015-1024, July 1999. Contents of the above articles are hereby incorporated by reference.

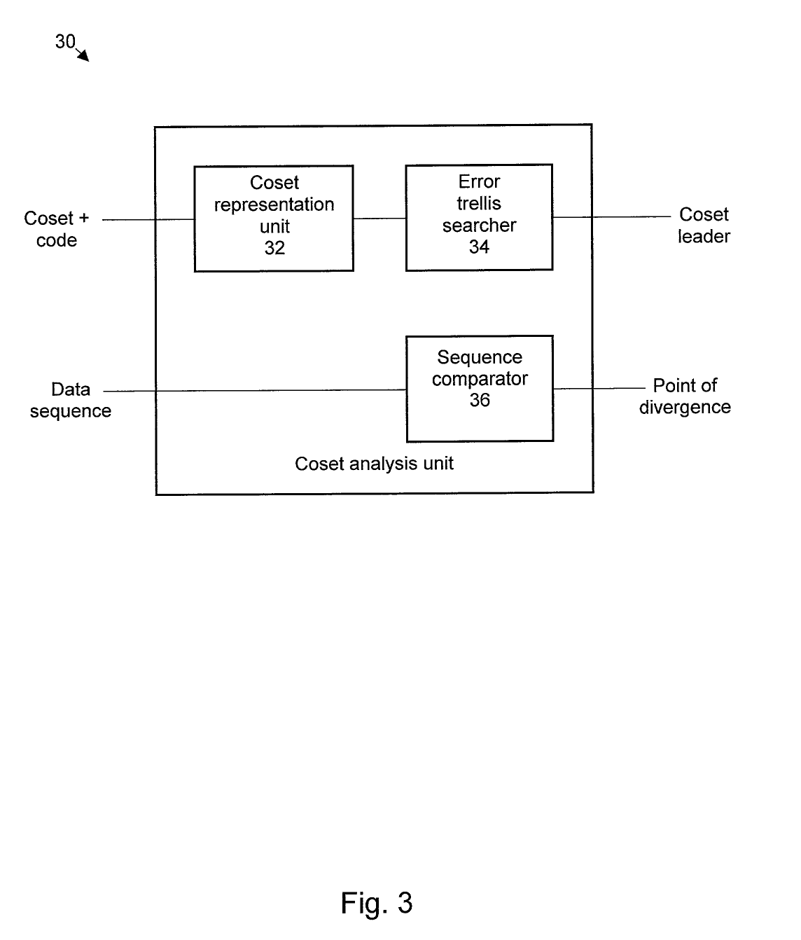

Reference is now made to FIG. 3, which shows a simplified block diagram of a Coset Analysis Unit 30. The Coset Analysis Unit 30 comprises a coset representation unit 32, an error trellis searcher 34, and a sequence comparator 36. The Coset Analysis Unit 30 serves in both the compressor and decompressor to represent and analyze a coset of a code. The Coset Analysis Unit 30 can analyze cosets of trellis codes. A trellis code is a linear code that can be described by a trellis diagram. Trellis codes include convolutional codes and block codes. In a preferred embodiment the code is a time-varying error control code, generally a time-varying convolutional code.

In order to analyze a coset, coset representation unit 32 first constructs a time-varying error trellis representing the coset. The inputs to the coset representation unit 32 are definitions of the coset and of the code from which the coset is derived. In the preferred embodiment the code is a convolutional code, and the coset is defined by a syndrome sequence y.

Coset representation unit 32 constructs the time-varying error trellis as follows. In a preferred embodiment the input code is represented as a concatenated sequence of predetermined code modules, as described below. The time-varying convolutional code C is composed of members of a family of codes F. Code family F is based on a family of b binary convolutional sub-codes {C1, C2, . . . , Cb}, where all sub-codes have the same state space. Code C may be represented as an ordered sequence of sub-codes. For a given set of sub-codes, coset representation unit 32 is capable of representing all cosets of all codes having associated sets of sub-codes with the same state space.

The coset representation unit 32 first partitions the syndrome sequence y into fixed length segments of length d. For binary signaling, a set of 2^{d}b trellis modules is sufficient for the composition of time-varying error-trellises for all the cosets of any version of the time-varying code C. The modules are drawn and connected dynamically according to the value of segments of y. The paths through a given error trellis indicate the members of the coset of C associated with the syndrome used to construct the error trellis.

Error trellis searcher 34 analyzes the error trellis to identify the coset leader. The coset leader is the minimum Hamming weight member of the coset. In a preferred embodiment the coset leader is identified by performing a Viterbi algorithm search through the error trellis.

In a preferred embodiment, the Coset Analysis Unit 30 is used to determine if a given sequence is the coset leader. Sequence comparator 36 compares the input sequence with the detected coset leader to verify that the sequences are identical. In a further preferred embodiment, the Coset Analysis Unit 30 is used to determine if a given sequence is a member of the coset. When determining presence of a sequence in a coset, the search for the coset leader may be omitted. The error trellis searcher 34 follows the path defined by the input sequence through the trellis to verify that such a path exists. If the path exists, the input sequence is a member of the coset.

In a preferred embodiment a coset is defined by a syndrome sequence y formed by multiplying an input sequence x by the code's parity check matrix. For this embodiment, sequence x is a member of the coset being analyzed by definition, and the verification that such a path exists is unnecessary.

Once the error trellis is constructed, error trellis searcher 34 identifies the coset leader by searching the error trellis for the path with the minimum Hamming weight. In the preferred embodiment the search is performed using a Viterbi algorithm. In a preferred embodiment when more than one minimum weight path through the trellis exists, a decision rule is implemented to select one of the paths as coset leader.

Sequence comparator 36 provides additional analysis capabilities to the coset analysis unit 30. Sequence comparator 36 is used to analyze the properties of an input sequence. In one preferred embodiment, the sequence comparator determines whether the input sequence is the coset leader of the given coset. In another embodiment, the sequence comparator determines whether the input sequence is a member of the coset.

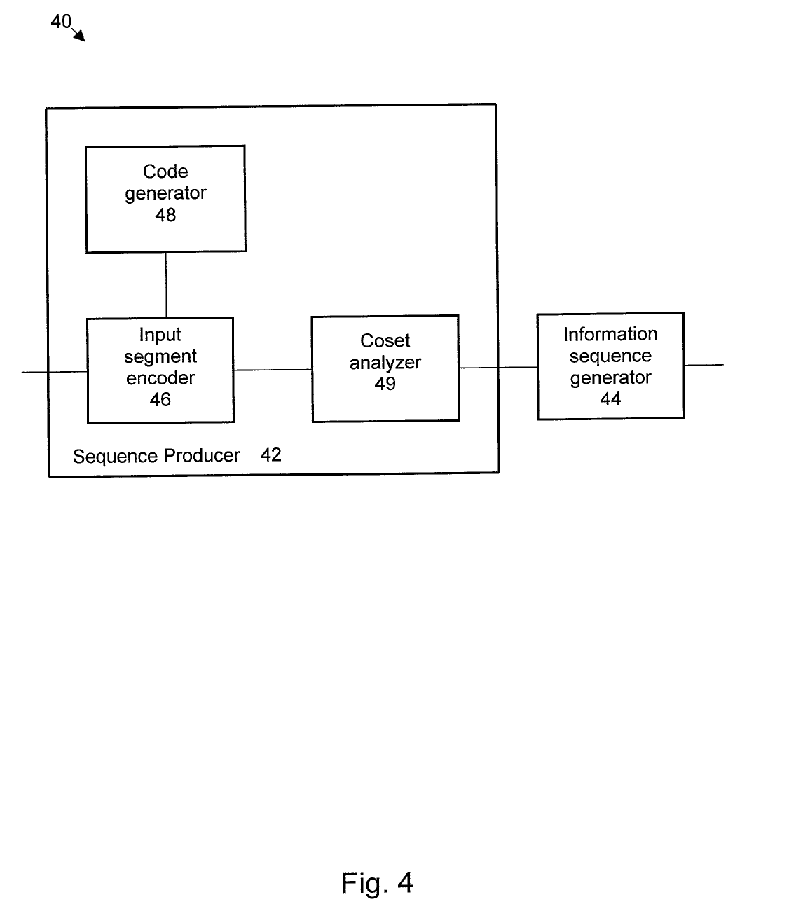

Reference is now made to FIG. 4, which shows a simplified block diagram of an embodiment of a lossless data sequence compressor 40. Data compressor 40 comprises sequence producer 42, and information sequence generator 44. Sequence producer 42 comprises input segment encoder 46, code generator 48, and coset analyzer 49.

Sequence producer 42 compresses the input sequence into the syndrome of a coset of a code, while ensuring that the Syndrome Constraint is fulfilled. Code generator 48 iteratively constructs a compression code which is used by input segment encoder 46 to compress input sequence x. In the preferred embodiment the compression code is an error correction code having defined cosets. As described above, each coset is associated with a sequence denoted a syndrome, and has an identifiable member denoted a coset leader. In the preferred embodiment, code generator 48 constructs the compression code to ensure that sequence x is a coset leader of one of the cosets of the code, thereby fulfilling the Syndrome Constraint. Coset analyzer 49 analyzes the compressed segment and the compression code in order to identify the coset leader. The coset leader is compared to the input data sequence to check the Syndrome constraint. The iterative code formation process is continued until the entire sequence has been compressed. Information sequence generator 44 then generates an information sequence defining the code and forms an output sequence by attaching it to the syndrome sequence. Data compressor 40 outputs a compressed sequence that identifies a compression code and a coset of the code, such that input sequence x is a coset leader of the specified coset.

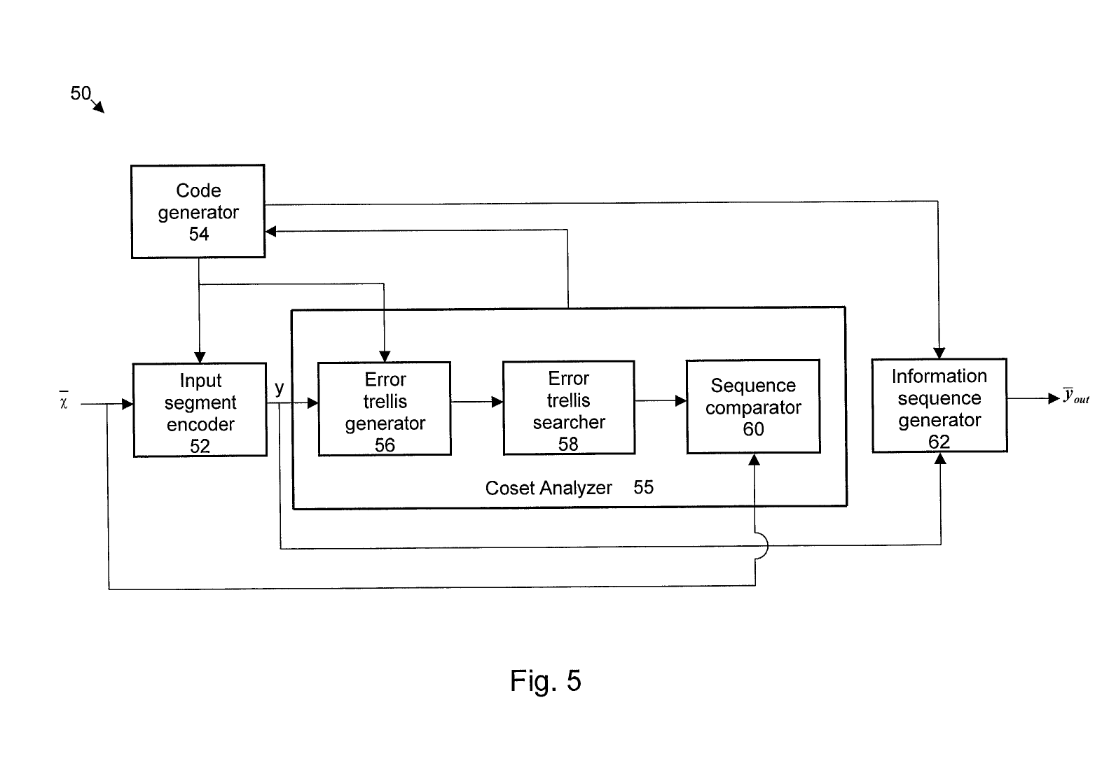

Reference is now made to FIG. 5, which is a simplified block diagram of an additional preferred embodiment of a lossless data sequence compressor 50. Data compressor 50 comprises input segment encoder 52 and code generator 54 to generate a compressed sequence. Data compressor 50 additionally comprises a coset analyzer 55 that detects whether the Syndrome Constraint is satisfied by the sequence produced by input segment encoder 52. The coset analyzer 55 comprises an error trellis generator 56, error trellis searcher 58, and sequence comparator 60. Data compressor 50 further comprises information sequence generator 62. Information sequence generator 62 attaches an information sequence to the sequence generated by the encoder to form an output sequence.

In the preferred embodiment, the compression code is a time-varying convolutional code. Input segment encoder 52 compresses input sequence x into sequence y by performing:

y=xH^{t}

where H^{t} is the transpose of matrix H. Sequence y is the syndrome of the coset containing x.

As the input sequence properties are not known in advance, the compression code is created dynamically to ensure that x is a coset leader of a coset of the code. The code is created iteratively by code generator 54 as an ordered sequence of sub-codes selected from a predetermined set of sub-codes. When the compression code is a time-varying convolutional code, the compression code is formed from a set of convolutional sub-codes having the same state space. Code generator 54 generates the code using feedback received from input segment encoder 52 and from sequence comparator 60.

Code generator 54 generates the compression code and corresponding parity matrix H by an iterative trial-and-error procedure. Code generator 54 selects a first sub-code C₁ with parity check matrix Hᵢ, and forms an initial compression code C′ using C₁. Next, input segment encoder 52 encodes a sub-segment x₀ from the beginning of the input sequence x into a compressed sub-segment y₀ using code C′. After a segment of x has been encoded, the coding process is halted, and coset analyzer 55 checks whether the coding process so far satisfies the Syndrome Constraint.

To check the Syndrome Constraint, trellis generator 56 generates an error trellis segment corresponding to the compressed sub-segment y₀. Trellis generator 56 divides y₀ into fixed length segments. It then chains the error trellis modules corresponding to each of the syndrome segments together to form an error trellis. The error trellis defines a coset of code C′ whose syndrome is y₀. Next error trellis searcher 58 searches for the minimum Hamming weight path through the error trellis segment, thereby identifying the coset leader. In the preferred embodiment, the search is performed using the Viterbi algorithm. If the error-trellis thus constructed is sufficiently large, a trace back procedure through the processed error-trellis may yield a single optimal path x′. Generally, if the number of connected modules is greater than five times the constraint length of the code a coset leader can be accurately determined.

The length of the syndrome segment determines the number of modules required to construct the error trellis. In a binary signal set, given a syndrome segment of length L the number of modules required for each sub-code is 2^{L}. Selecting a small syndrome segment length reduces the number of required modules.

After x′ is found, sequence comparator 60 performs a symbol-by-symbol comparison between x′ and x₀. If the two data sequences are identical, the Syndrome Constraint is satisfied and the compression process continues by extending the compression code using sub-code C₁. A longer segment of input sequence x is compressed, more modules corresponding to the newly generated segments of y are appended to the error-trellis, and coset leader x′ is extended. The extended x′ is compared once more to sequence x. Once a deviation of x from the optimal path x′ is detected, the Syndrome Constraint is violated. The generation of the bits of y is stopped, and code generator 54 replaces the sub-code C₁ with Cj, another member of set C, and regenerates code C′ using sub-code Cj.

In the preferred embodiment, code generator 54 modifies the compression code by changing the time-varying matrix H so that subsequent bits of x are encoded with the newly selected code. Matrix H is modified by replacing some columns of the previous parity check matrix H with columns taken from the scalar parity-check matrix corresponding to Cⱼ. Input segment encoder 52 generates a new compressed segment y, using the modified matrix H. Trellis generator 56 now reconstructs and/or extends the error trellis by replacing some modules of the error-trellis with the modules corresponding to the modified matrix H and new segments of y. The process of identifying the currently selected sub-code Cⱼ repeats periodically, and may require several iterations.

In a preferred embodiment, the sub-codes selected to form C are chosen to maximize the coding rate k/n of each selected sub-code used to form C′ while satisfying the Syndrome Constraint. The resulting code C therefore provides a high degree of compression.

In a preferred embodiment, if the sub-code is changed to one that has a lower coding rate, the code generator 54 replaces a minimum number of sub-code modules. If a deviation of the input sequence from the least-weight path is detected at the i-th sub-segment, the i-th sub-code module is replaced and the Syndrome Constraint is rechecked. If the Syndrome Constraint is still not satisfied, replacement of some previous sub-code modules is required.

When all the bits of x are encoded, the information sequence generator 62 appends an information sequence to y, to form the compressed output sequence yₒᵤₜ. The information sequence identifies the compression code used to form yₒᵤₜ and the coset for which the input sequence x is coset leader. In the preferred embodiment the information sequence contains the indices of the members of C that participated in the compression and a pointer to the locations where the convolutional code was changed. The information sequence is used during decompression to regenerate the error trellis.

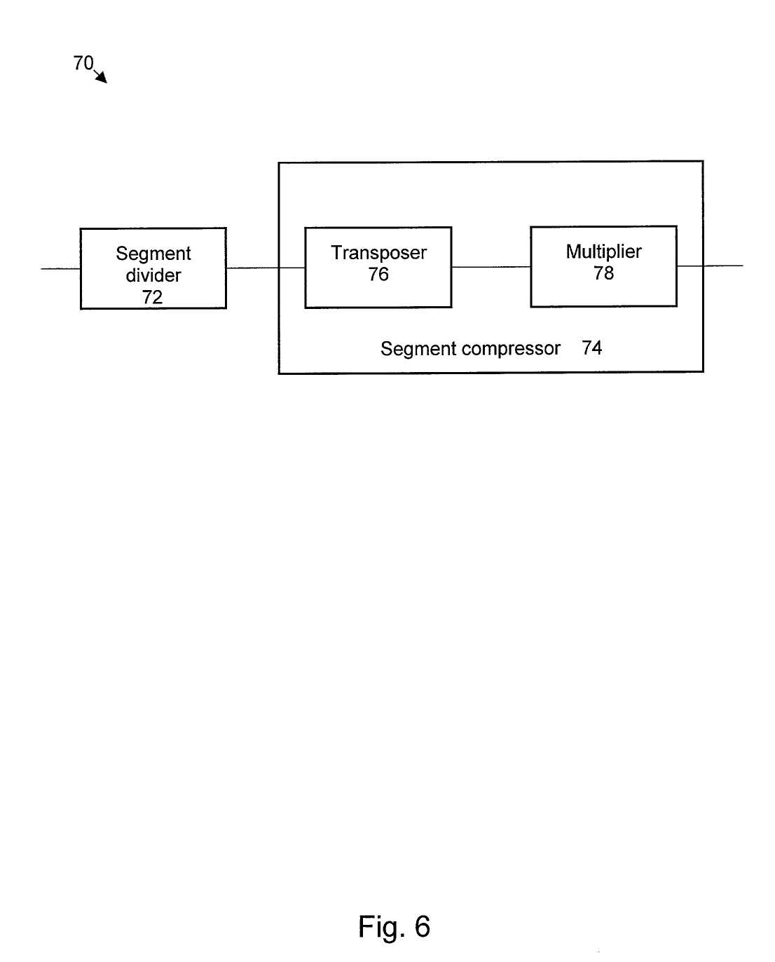

Reference is now made to FIG. 6, which is a simplified block diagram of an embodiment of an input segment encoder 70. When the compression process is performed as described above, the input segment x is effectively sub-divided into sub-segments, and each sub-segment is compressed with an associated sub-code selected from set C. Input segment encoder 70 comprises segment divider 72 which subdivides the input sequence, and segment compressor 74 which compresses each segment. Segment compressor 74 comprises transposer 76 and multiplier 78. The input segment encoder 70 works in conjunction with a code generator that provides the compression code used to compress the input sequence.

Segment divider 72 divides the input data sequence into variable length sub-segments. Each of these segments is compressed by segment compressor 74 with an associated sub-code dynamically selected by the code generator for the sub-segment.

In the preferred embodiment the sub-code is provided by the code generator as a parity check matrix. Transposer 76 transposes the sub-code parity check matrix. Multiplier 78 then encodes each of the sub-segments by multiplying the sub-segment by the transposed parity check matrix of the associated sub-code.

The code generator and input segment encoder 70 dynamically adjust the sub-segment length and associated sub-codes to ensure that the Syndrome Condition is met. The sub-code selected by the code generator for sub-segment i depends on the code selected for segment i−1. In other words, the error-trellis is a finite state machine that has a “memory”, i.e., the least-weight path for segment i-1 of the error-trellis terminates at some state and the value of this state also affects the sub-code selected for segment i.

The length of a sub-segment of x encoded by a given sub-code is variable, and determined by the encoding process. In the preferred embodiment, the input segment encoder 70 has a sub-segment length adjustment, which may be used to place limits on the sub-segment length. In a preferred embodiment, the input segment encoder 70 ensures that the number of consecutive elements of the input sequence x that are encoded with any given sub-code does not exceed a predetermined number. When the predetermined number is exceeded, the encoding is halted, and the code generator is signaled to modify the parity matrix H. Changing the sub-code ensures that the number of consecutive error trellis modules from any given sub-code does not exceed a certain threshold. In another preferred embodiment, the above threshold is checked only when the input sequence is being compressed using a sub-code whose coding rate is below a predetermined threshold.

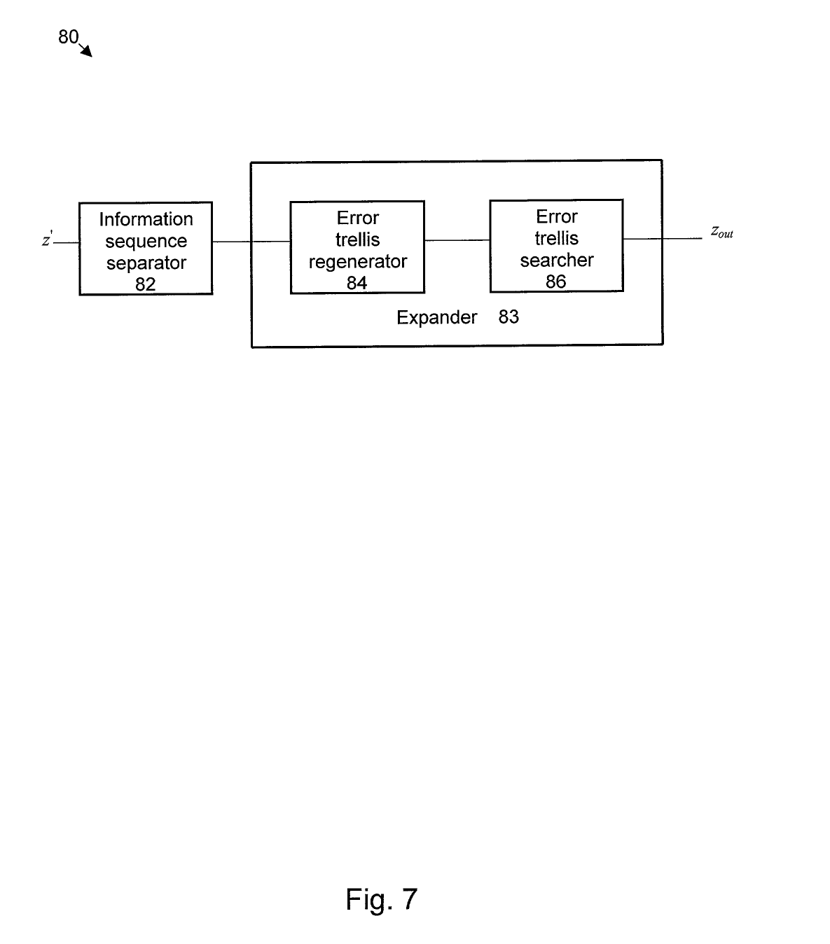

Reference is now made to FIG. 7, which shows a simplified block diagram of an embodiment of a lossless data sequence decompressor 80. Data sequence decompressor 80 comprises information sequence separator 82, and expander 83. Expander 83 comprises error trellis regenerator 84, and error trellis searcher 86.

Decompressor 80 receives a compressed input sequence z′, which comprises a syndrome sequence, and an information sequence. Information sequence separator 82 removes the information sequence from sequence z′, and analyzes it to determine which sub-code was used to generate each segment of the syndrome sequence. In a preferred embodiment the information sequence contains the indices of the members of C that participated in the compression and a pointer to the locations where the convolutional code was changed.

Expander 83 decompresses the portion of the input sequence z′ remaining after the information sequence is removed. The remaining portion identifies a coset of the compression code. In the preferred embodiment the coset is identified by a syndrome sequence. Error trellis regenerator 84 generates an error trellis corresponding to the coset. Error trellis regenerator 84 comprises error trellis modules for all of the sub-codes within the set of sub-codes C used by the compressor. First error trellis regenerator 84 divides the syndrome into fixed length segments. Error trellis regenerator 84 then chains the error trellis modules corresponding to each of the syndrome segments together. For each segment of the syndrome, error trellis regenerator 84 selects an error trellis module from the set of error trellis modules corresponding to the sub-code used to generate that segment. The sub-code is determined from the information sequence provided by the information sequence separator 82. The error-trellis structure is uniquely specified by the syndrome and by the information sequence.

Error trellis searcher 86 searches the error trellis for the coset leader. In the preferred embodiment, the search for the coset leader is performed by searching the error trellis for a minimum Hamming weight path using the Viterbi algorithm. The coset leader serves as the decompressor output sequence zₒᵤₜ. Sequence zₒᵤₜ specifies the compressor input sequence without error.

In a preferred embodiment, when more than one minimum weight path through the trellis exists, a decision rule is implemented to select one of the paths as coset leader. To ensure correct decompression, the decision rule used must be consistent with the rule used by the compressor to generate the compressed sequence.

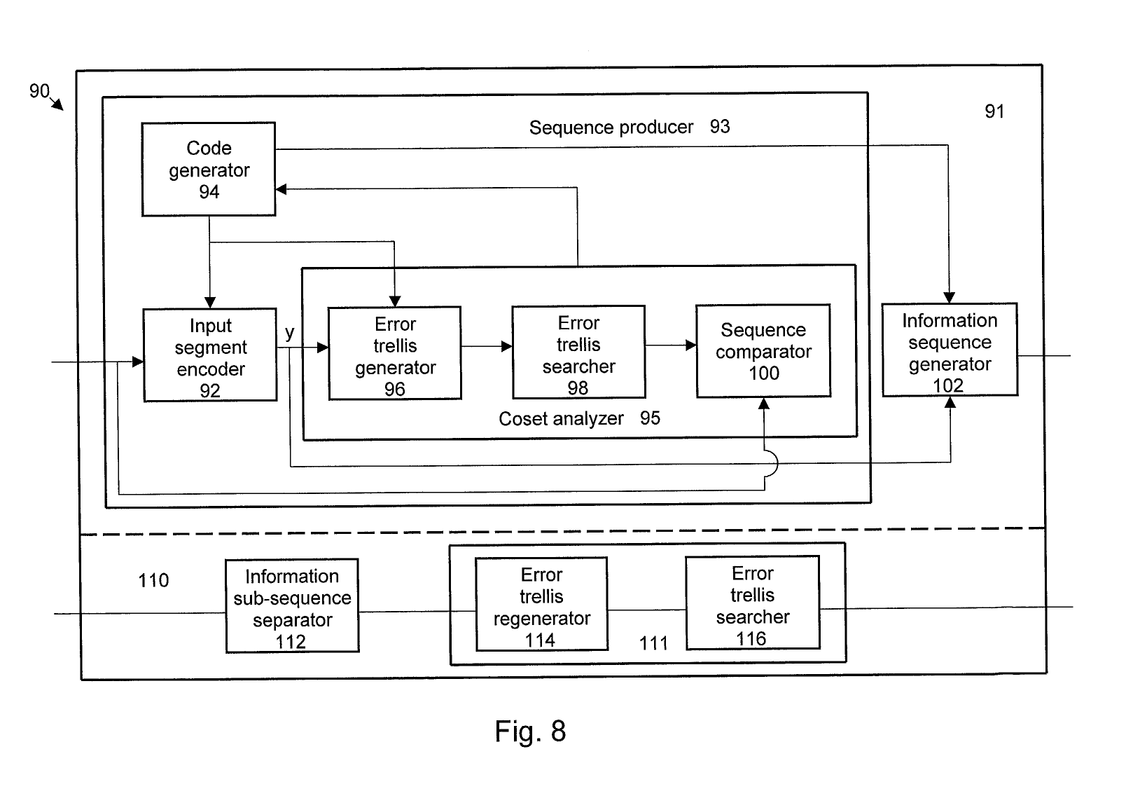

Reference is now made to FIG. 8, which is a simplified block diagram of a communication device. Communication system 90 contains two signal converters, the first signal converter 91, and the second signal converter 110. The first signal converter 91 performs lossless compression on an input data sequence. Generally the compression is performed in preparation for transmission of the data sequence over a data channel. The first signal converter 91 comprises sequence producer 93 for producing a compressed sequence, and information sequence generator 102 to attach an information sequence to the compressed sequence. Sequence producer 93 comprises input segment encoder 92, and code generator 94 to generate a compressed sequence, coset analyzer 95 to detect whether the Syndrome Constraint is satisfied by the compressed sequence. The coset analyzer 95 comprises an error trellis generator 96, error trellis searcher 98, and sequence comparator 100.

The second signal converter 110 performs lossless data decompression on a received data sequence. Generally the input signal is decompressed after its reception from a data channel. Second signal converter 110 comprises information sequence separator 112, and an expander 111. Expander 111 comprises error trellis regenerator 114 and error trellis searcher 116.

The first signal converter 91 of communication system 90 performs the data compression similarly to data sequence compressor 50, as described above. Sequence producer 93 produces a compressed sequence that is the syndrome of a dynamically generated error correction code. In a preferred embodiment the compression code is a convolutional code. Input segment encoder 92 compresses input sequence x into sequence y using a compression code with parity matrix H by performing:

y=xH^{t}

where H^{t} is the transpose of matrix H. In order to ensure that x is a coset leader of a coset of the compression code, code generator 94 constructs the code iteratively, by correctly ordering a sequence of sub-codes selected from a predetermined set of sub-codes. In the preferred embodiment, code selector 94 generates matrix H iteratively using feedback received from sequence comparator 100 to ensure that the Syndrome Constraint is fulfilled.

To check the Syndrome Constraint, trellis generator 96 generates an error trellis segment corresponding to a compressed sequence. Error trellis searcher 98 searches the error trellis and identifies the coset leader by determining a minimum Hamming weight path through the error trellis. After the coset leader is found, sequence comparator 100 performs a symbol-by-symbol comparison between the input sequence and the coset leader identified by error trellis searcher 98. If the two data sequences are identical, the Syndrome Constraint is satisfied and the compression process continues. Once a deviation of x from the coset leader is detected, the Syndrome Constraint is violated. The generation of the bits of y is stopped, and the code generator 94 replaces the current compression sub-code with a new compression sub-code. The compression process is repeated until sequence x is compressed in its entirety. When all the bits of x are encoded, the information sequence generator 102 appends an information sequence to y, to form the compressed output sequence yₒᵤₜ. The information sequence identifies the compression code used to form yₒᵤₜ.

The second signal converter 110 of communication system 90 performs the data decompression similarly to data sequence decompressor 80 described above. The input sequence to the second signal converter 110 is a compressed input sequence z′, comprising a syndrome sequence, and an information sequence. Information sequence separator 112 removes the information sequence from sequence z′, and analyzes it to determine which sub-code was used to generate each segment of the syndrome sequence. Expander 111 decompresses the compressed sequence into the coset leader specified by the code and syndrome. Error trellis regenerator 114 generates an error trellis corresponding to the syndrome sequence by chaining together error trellis modules according to the code identified by information sequence separator 112 and the syndrome segment. Error trellis analyzer 116 searches the error trellis for the minimum Hamming weight path, thereby identifying the coset leader. In the preferred embodiment, the search for the coset leader is performed using the Viterbi algorithm. The coset leader serves as the decompressor output sequence zₒᵤₜ. Sequence zₒᵤₜ specifies the compressor input sequence without error.

Communication system 90 is applicable to any device that incorporates data compression, and thus has several preferred embodiments in both the server and the client sides of data communication systems. In a preferred embodiment communication system 90 comprises one of the following devices: a router, a data switch, a data hub, a terminal for wireless communication, a terminal for wire communication, a personal computer, a cellular telephone handset, a mobile communication handset, and a personal digital assistant.

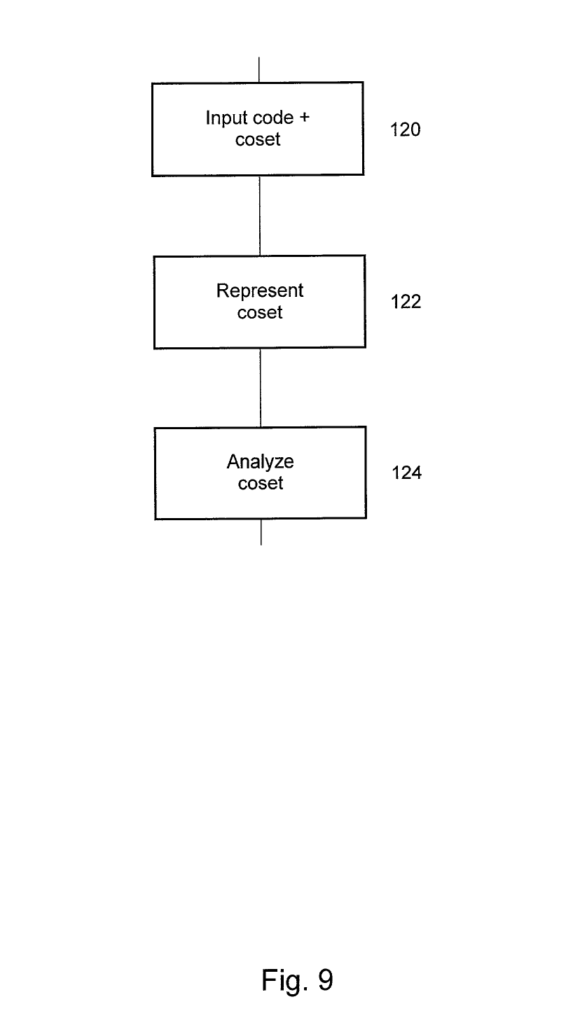

Reference is now made to FIG. 9, which is a simplified flow chart of a method for analyzing a coset. In step 120 an error correction code and a coset of the code are input. In step 122 the coset is represented as a time-varying error trellis. Every sequence of the coset is represented as a path through the error trellis. In a preferred embodiment the code is a convolutional code.

In the preferred embodiment the error trellis is generated by concatenating a sequence of error trellis modules selected from a predetermined set of modules, where the sequence of the modules is dictated by the coset being represented. In a preferred embodiment, the module sequence is determined from a syndrome sequence associated with the coset.

In step 124 the coset is analyzed to determine its properties. In a preferred embodiment the analysis consists of detecting a coset leader of the coset. A coset leader is detected by performing a search of the error trellis constructed in step 122 to identify a minimum Hamming weight path through the trellis. In a preferred embodiment the search is performed as a Viterbi algorithm search.

In another preferred embodiment the analysis of step 124 consists of determining whether a data sequence is a member of the coset. The analyzer traces a path given by the sequence through the trellis. If the sequence is contained in the trellis the sequence is a member of the coset. Otherwise, the sequence is not a member of the coset.

In a preferred embodiment a coset is defined by a syndrome sequence y formed by multiplying an input sequence x by the code's parity check matrix. For this embodiment, sequence x is a member of the coset being analyzed by definition, and the verification that such a path exists is unnecessary.

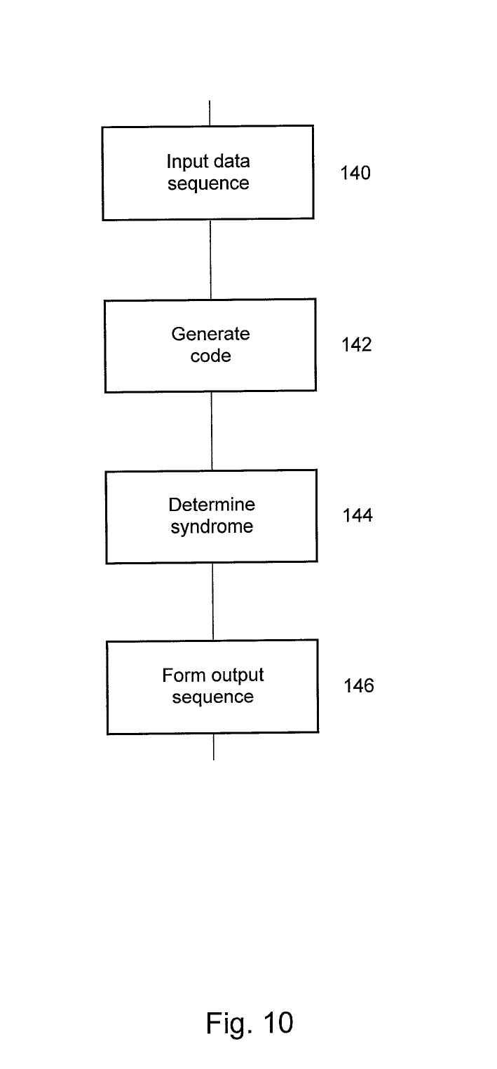

Reference is now made to FIG. 10, which is a simplified flow chart of a method for compressing an input sequence. In step 140 a data sequence is input. A compression code is generated in step 142. The compression code generated is an error correction code having cosets. Each coset has a unique syndrome and coset leader. The compression code is generated so that the input sequence is a coset leader of one of the cosets of the compression code. In a preferred embodiment the compression code is formed by selecting a sequence of sub-codes from a predetermined set of codes. The code sequence is determined from the input data sequence being compressed.

In step 144 the input sequence is compressed into the syndrome of the coset for which the input sequence is coset leader. The syndrome is one component of the compressed output sequence.

In step 146 an output sequence is formed. First an information sequence is formed. The information sequence provides a definition of the error-correction code used to compress the input signal. The information sequence and the syndrome are then combined to form the output sequence. The combined information of the syndrome sequence and the information sequence provides a complete definition of the input sequence that can be used during a decompression process to reconstruct the input sequence.

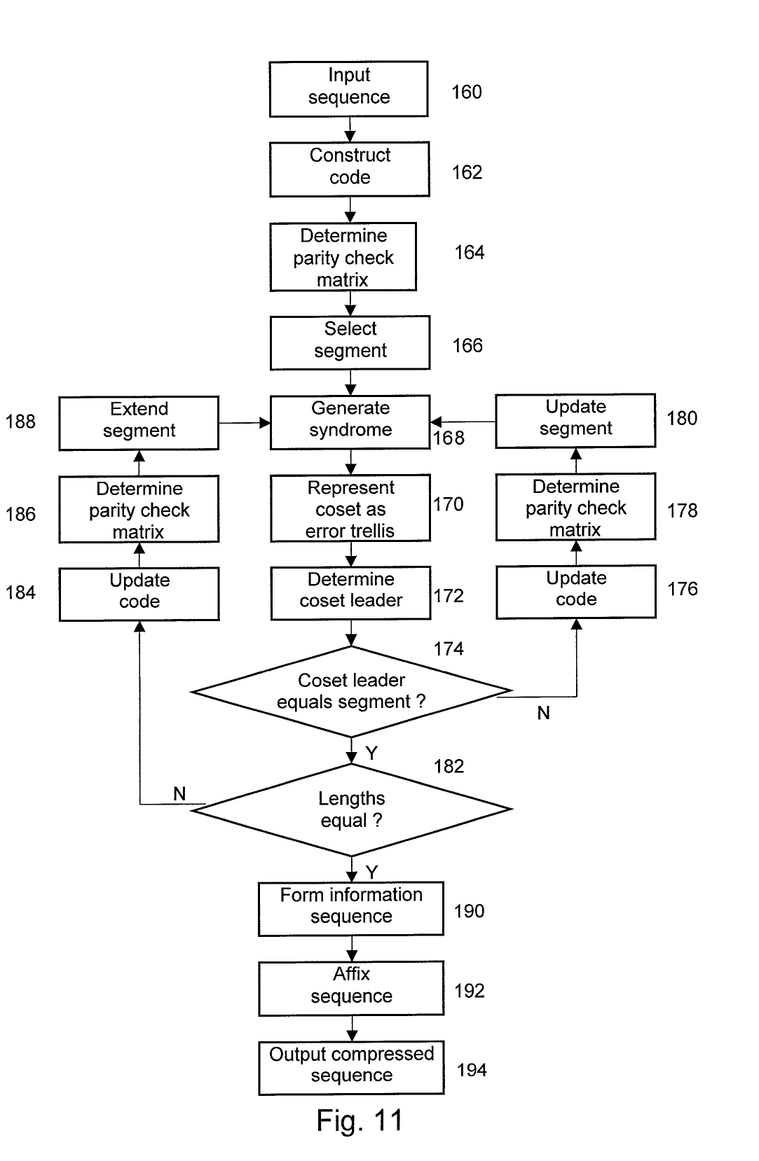

Reference is now made to FIG. 11, which is a simplified flow chart of an additional method for compressing an input sequence. The method begins at step 160 by inputting an input data sequence. In step 162 an initial error correction code is constructed. The error correction code has cosets, and each coset has a unique syndrome and coset leader. In a preferred embodiment the error correction code is a time-varying convolutional code. In a further preferred embodiment, the time-varying convolutional code is constructed by forming an ordered sequence of convolutional sub-codes. The sub-codes forming the convolutional code have the same state space.

A parity check matrix for the initial error correction code is created in step 164. The parity check matrix is used later in the compression process. In step 166 a segment of the input sequence is selected. The segment is generally from the beginning of the input sequence, and is progressively extended during the compression process until it encompasses the entire input sequence.

The main compression loop begins at step 168. The input segment selected in step 166 is compressed into a syndrome sequence using the initial error correction code constructed in step 162. The syndrome is formed by multiplying the input segment by the transpose of the parity check matrix determined in step 164. An embodiment of a method for performing the multiplication is described below.

Next, in step 170, the coset associated with the syndrome formed in step 168 is represented as an error trellis. In a preferred embodiment, the coset is formed by concatenating a sequence error trellis modules. The error trellis modules are taken from a predetermined set, and the sequence is determined by the code used for compression and the syndrome formed in step 168. An embodiment of a method for representing a coset as an error trellis is described below.

The error trellis is searched in step 172 to determine the coset leader of the coset it represents. The coset leader is identified by searching the error trellis to determine a minimum Hamming weight path through it. In a preferred embodiment the search is performed as a Viterbi algorithm search.

In step 174 the coset leader is compared to the input sequence. If the sequences differ, the error correction code is updated is step 176, and a parity check matrix for the updated code is determined in step 178. When the error correction code is formed as a concatenated sequence of sub-codes as in the preferred embodiment described above, updating the code is done by reselecting the sequence of sub-codes forming the code. Additionally, in step 180, the input data sequence segment is updated. The compression loop is reentered at step 168 with the redefined code and segment.

If the comparison performed in step 174 indicates that the coset leader and input sequence segment are identical, a test is performed in step 182 to determine whether the entire input sequence has been compressed. The length of the coset leader sequence is compared to the length of the full input sequence. If the two sequences are the same length, the entire input sequence is compressed, and the compression loop may be exited.

If the entire sequence has not been compressed, the error correction code is updated in step 184. A parity check matrix for the updated code is determined in step 186. The updated code extends the code previously used for compression, so as to compress a larger input sequence segment. When the error correction is formed as a concatenated sequence of sub-codes as in the preferred embodiment described above, extending the code is done by reselecting the sequence of sub-codes forming the code. In step 188, the input data sequence segment is updated. The compression loop is reentered at step 168 with the redefined code and segment.

After the compression loop is exited, the compression process is terminated by performing the following three steps. In step 190 an information sequence is formed. The information sequence indicates the error correction code used for compression. Information about the code is needed to reconstruct the original input sequence during the decompression process. Next, in step 192, the final compressed sequence is formed by affixing the information sequence to the syndrome sequence. The compressed sequence is output in step 194, and the compression method ends.

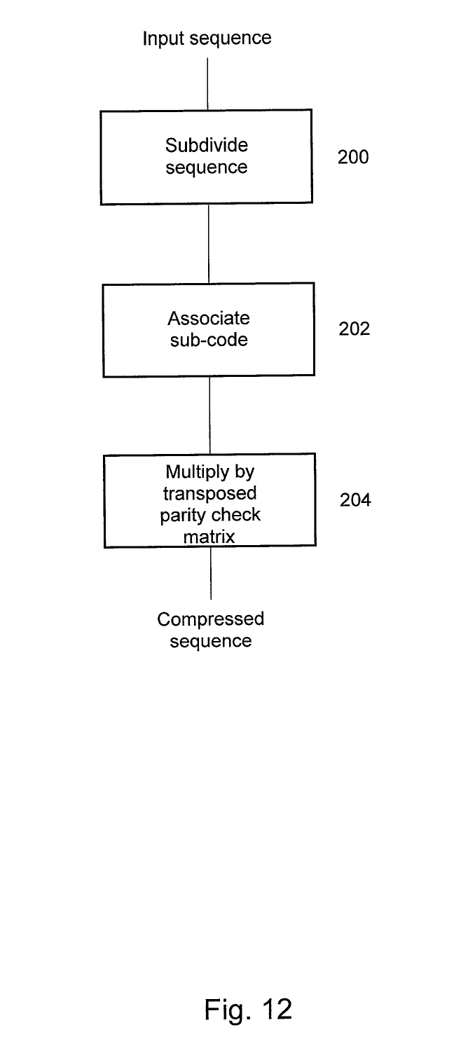

Reference is now made to FIG. 12, which is a simplified flow chart of a method for multiplying an input sequence by the transpose of a parity check matrix to form a syndrome sequence. In step 200, the input sequence is divided into sub-segments. The length of the sub-segments is variable. A sub-code is associated with each of the sub-segments in step 202. The sub-code selected for a given sub-segment depends on the code selected for the previous segment. Finally, in step 204, each input data segment is multiplied by the transpose of a parity check matrix of the sub-code associated with the sub-segment. In a preferred embodiment, the length of each sub-segment is limited to no more than a predetermined length.

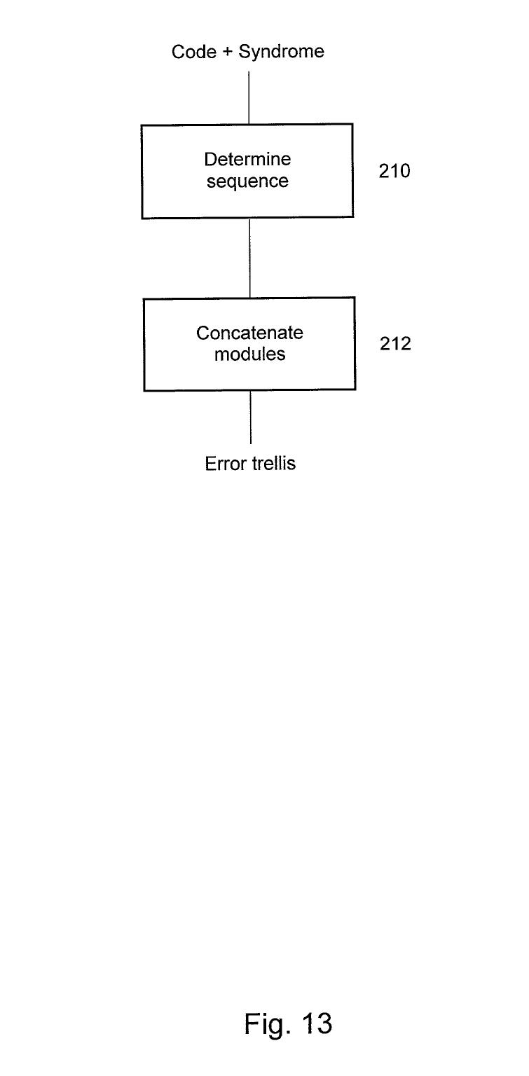

Reference is now made to FIG. 13, which is a simplified flow chart of a method for representing a coset as an error trellis. The coset being represented is defined by a given error correction code and syndrome. First, a sequence of error trellis modules is determined in step 210. The modules are selected from a predetermined set of modules. The sequence of modules is determined from the error correction code and syndrome sequence. In step 212 the error trellis modules are concatenated in the sequence determined in step 210, thereby forming the error trellis.

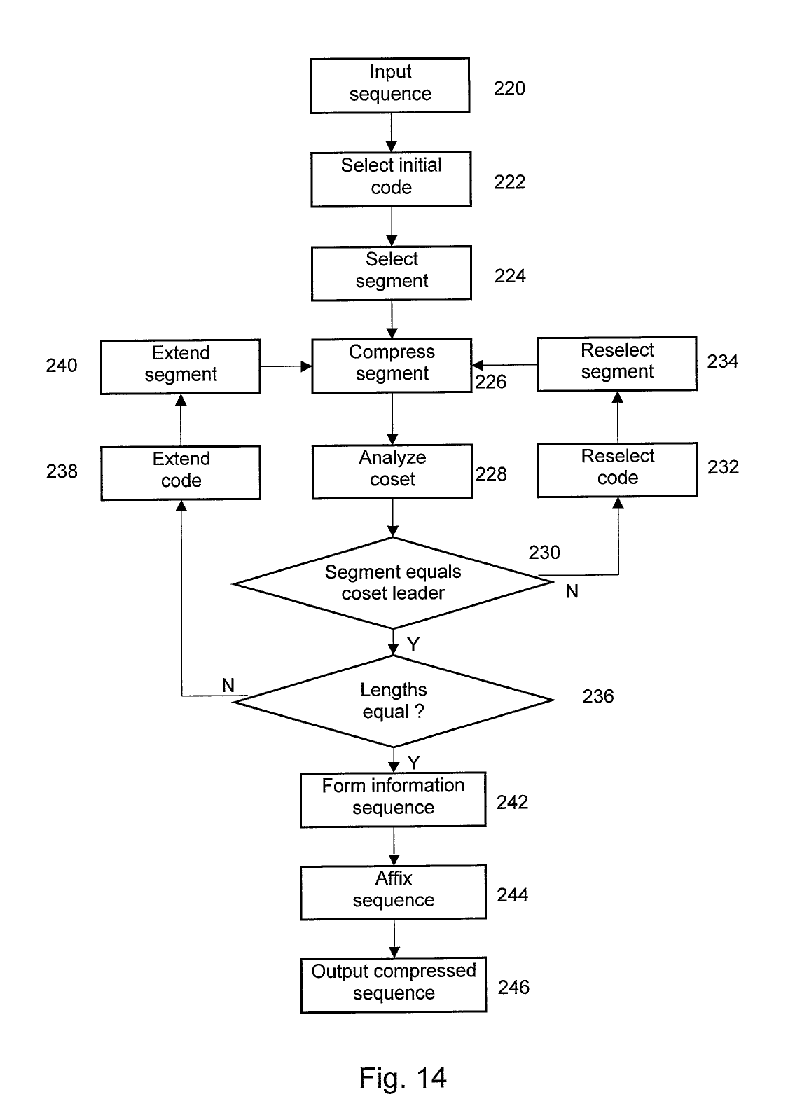

Reference is now made to FIG. 14, which is a simplified flow chart of an additional method for compressing an input sequence. The method begins at step 220 by inputting an input data sequence. In step 222 an initial compression code is constructed. The compression code has cosets, and each coset has a unique syndrome and coset leader. In a preferred embodiment the compression code is a time-varying error correction code. In a further preferred embodiment the compression code is a time-varying convolutional code.

In step 224 a segment of the input sequence is selected. The segment is generally from the beginning of the input sequence, and is progressively extended during the compression process until it encompasses the entire input sequence.

The main compression loop begins at step 226. The input segment selected in step 224 is encoded into a compressed sequence using the initial compression code constructed in step 222. In a preferred embodiment the compressed sequence is the syndrome of a coset of the compression code. In an additional preferred embodiment the compressed sequence is formed by multiplying the input segment by the transpose of the compression code's parity check matrix.

Next, in step 228, the coset associated with the compressed sequence formed in step 226 is analyzed to determine its coset leader. Preferred embodiments of this analysis are described below. In step 230 the coset leader is compared to the input sequence. If the sequences differ, the compression code is reselected in step 232. Additionally, in step 234, the input data sequence segment is reselected. The compression loop is reentered at step 226 with the redefined code and segment.

If the comparison performed in step 230 indicates that the coset leader and input sequence segment are identical, a test is performed in step 236 to determine whether the entire input sequence has been compressed. The length of the coset leader sequence is compared to the length of the full input sequence. If the two sequences are the same length, the entire input sequence is compressed, and the compression loop may be exited. Otherwise the compression loop is reentered to compress a larger extent of the input sequence.

If the entire sequence has not been compressed, the compression code is extended in step 238. The extended code is able to compress a larger input sequence segment. In step 240, the input data sequence segment is extended as well. The compression loop is reentered at step 226 with the new compression code and input data segment.

If the lengths of the coset leader and the input sequence are equal, the compression cycle is ended and the following three steps are performed. In step 242 an information sequence is formed. The information sequence indicates the compression code used for to compress the input sequence. Information about the code is needed to reconstruct the original input sequence during the decompression process. Next, in step 244, the final compressed sequence is formed by affixing the information sequence to the syndrome sequence. The compressed sequence is output in step 246, and the compression method ends.

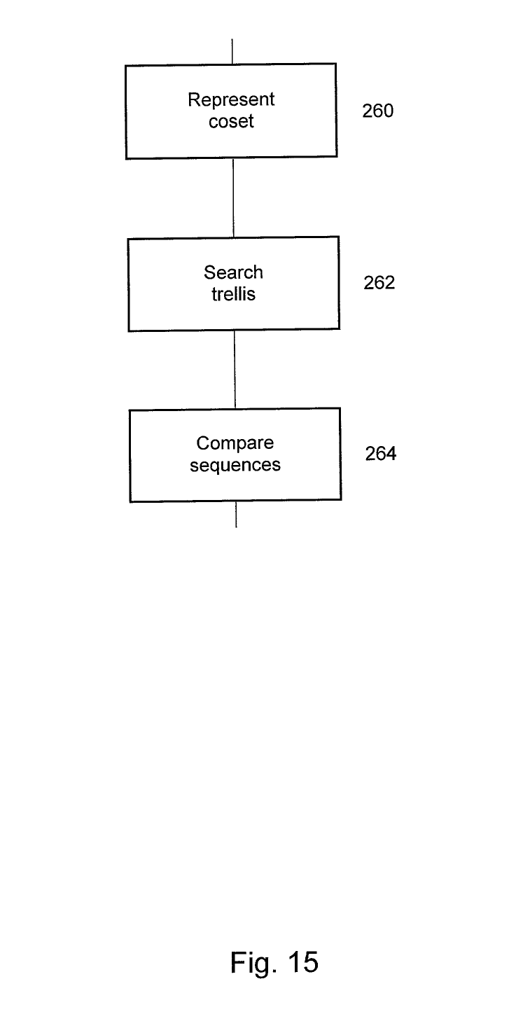

Reference is now made to FIG. 15, which is a simplified flow chart of a method for analyzing a coset. In a preferred embodiment, the coset is represented as an error trellis in step 260. In step 262 the error trellis is searched to identify a minimum Hamming weight path through the trellis, thus determining a coset leader. In a preferred embodiment the search is performed by Viterbi algorithm. Finally, in step 264, the coset leader is compared with the encoded sequence to determine whether the sequences are identical.

A preferred embodiment for representing the coset is described above in the embodiment of FIG. 13. The coset is formed by concatenating a sequence error trellis modules taken from a predetermined set, where the sequence is determined by the compression code and the compressed sequence.

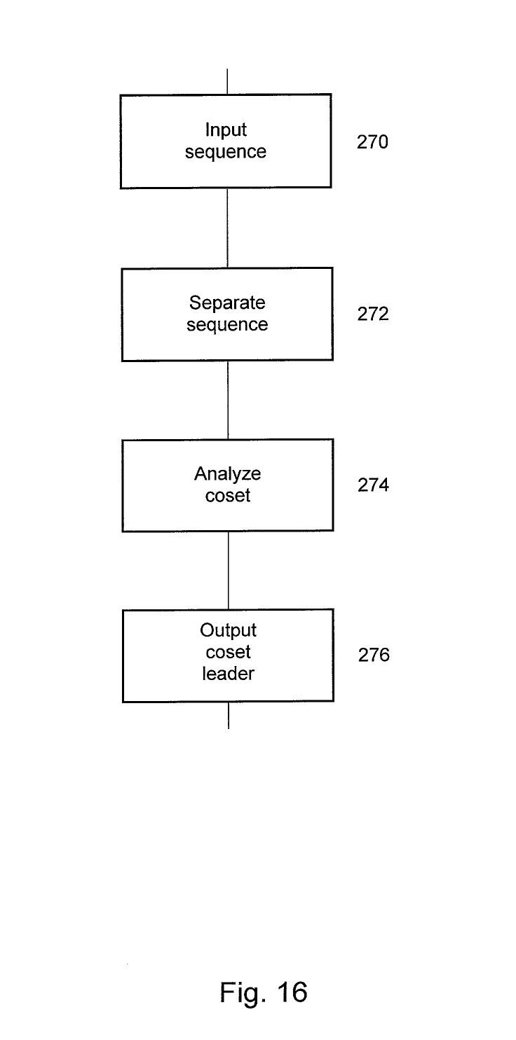

Reference is now made to FIG. 16, which is a simplified flow chart of a method for decompressing an input sequence. First the compressed sequence is input in step 270. In step 272 the compressed sequence is separated into a syndrome and an information sequence. Next, in step 274, the coset associated with the syndrome is analyzed to determine a coset leader for the coset. A preferred embodiment of a method for analyzing a coset is described below. The algorithm ends in step 276 by outputting the coset leader.

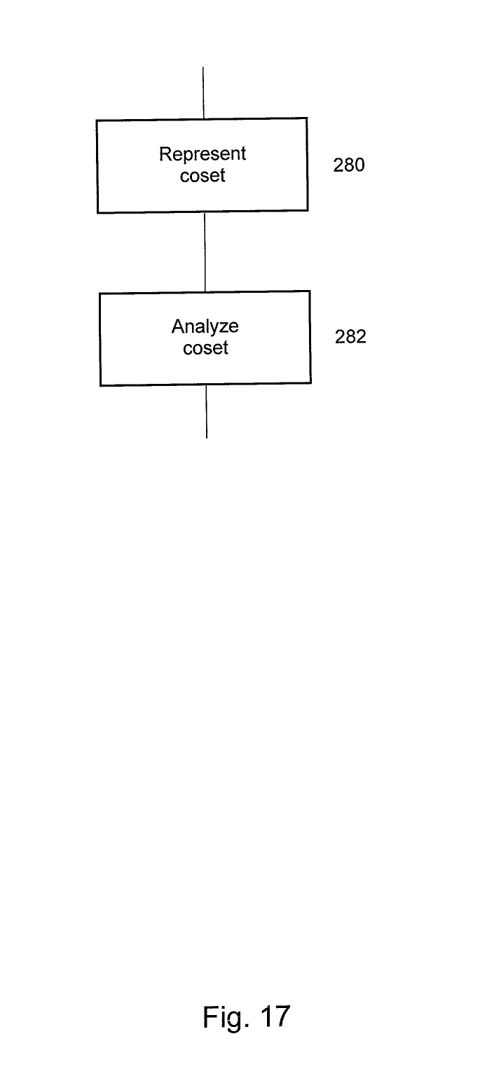

Reference is now made to FIG. 17, which is a simplified flow chart of a method for analyzing a coset. The coset is identified by an information sequence and a syndrome. The information sequence defines a code, and the syndrome specifies a particular coset of the code. In step 280 a coset of an error correction code is represented as a time-varying error trellis. Every sequence of the coset is represented as a path through the error trellis. The analysis of the coset is performed by searching the error trellis. The error trellis is searched in step 282 to identify a minimum Hamming weight path through the trellis. The path identified by the search is the coset leader. In a preferred embodiment the search is performed by Viterbi algorithm. A preferred embodiment for representing a coset as an error trellis is described above as the embodiment of FIG. 13.

A preferred embodiment is a method for communicating data. The communication method combines a compression method and a decompression method. In this method, a first data string is converted into a compressed output data sequence without loss of information and then transmitted. The compression is performed according to the method of FIG. 10. The communication method further comprises receiving a second data sequence and converting the second data string into a decompressed sequence without loss of information. The decompression is performed by the method of FIG. 16.

Some of the preferred embodiments described above refer to a binary signal set. The extension of the preferred embodiments described above to an N-ary signal set is straightforward. With N-ary signaling, given a syndrome segment length of L the number of different syndrome segment types is N^{L}. The number of error trellis modules must be adjusted according. Additionally, the Hamming distance between two sequences during N-ary signaling is the number of coordinates in which the two sequences differ.

An upper bound on the redundancy of the proposed apparatus and methods for data compression and decompression, including consideration of the information sequence, is based on the calculation of the average number of consecutive modules associated with the same code Ci. The average length can be upper-bounded based on the probability of first error event of maximum likelihood decoding of convolutional codes. For details see e.g., S. S. Pietrobon, “On the probability of error of convolutional codes”, IEEE Transactions on Information Theory, vol. IT-42, pp. 1562-1568, September 1996, contents of which are hereby incorporated by reference.

The above embodiments provide a universal lossless compression/decompression apparatus and methods to enable efficient data communication and processing. The above embodiments are capable of compressing and decompressing sequences generated by memoryless and autoregressive sources, with a near-optimum per-symbol length. The technique is applicable to a wide variety of signals, since knowledge of source statistics is not required. In fact, source statistics may change throughout the sequence. The compression is instantaneous and its efficiency is not affected by the length of the sequence. Simulation of the compression technique shows excellent performance for short as well as long sequences.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable subcombination.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

We claim:

1.A coset analyzer for use with time-varying error correction codes in data communications, the time-varying error correction code comprising cosets, each coset having a coset leader and syndrome, the analyzer comprising:
a coset representation unit for representing a coset of said code as a time-varying error trellis, the error trellis having a path corresponding to each member of the coset; and,
an error trellis searcher for searching said error trellis.

2. A coset analyzer for data communication according to claim 1, wherein said coset analyzer is operable to determine if a data sequence comprises a coset leader of said coset.

3. A coset analyzer for data communication according to claim 1, wherein said coset analyzer is operable to determine if a data sequence comprises a member of said coset.

4. A coset analyzer for data communication according to claim 2, wherein said error trellis searcher comprises weight determination functionality to determine a minimum Hamming weight path through said error trellis thereby to identify said coset leader.

5. A coset analyzer for data communication according to claim 1, wherein said time-varying error correction code comprises a convolutional code.

6. A coset analyzer for data communication according to claim 5, wherein said coset representation unit is operable to form said error trellis by concatenating a sequence of error trellis modules, and wherein said error trellis modules are selectable from a predetermined set of modules.

7. A coset analyzer for data communication according to claim 6, wherein said coset representation unit is operable to determine said sequence of error trellis modules from said convolutional code and from a syndrome sequence associated with said coset.

8. A coset analyzer for data communication according to claim 4, wherein said error trellis searcher is operable to find said coset leader by performing a Viterbi algorithm search of said error trellis to detect a minimum Hamming weight path through said error trellis.

9. A coset analyzer for data communication according to claim 4, wherein said coset analysis unit further comprises a sequence comparator associated with said error trellis searcher, and wherein said sequence comparator is operable to per form a symbol by symbol comparison of an input sequence with said coset leader thereby to determine a symbol at which said input sequence and said coset leader diverge.

10. A lossless data sequence compressor, for compressing an input data sequence into a compressed sequence without loss of information utilizing a dynamically-generated compression code, said compression code comprising a time-varying error correction code having cosets, each coset having a coset leader and syndrome, said compressor comprising:
a sequence producer for producing a compressed sequence comprising the syndrome of a coset of said compression code, such that said input sequence comprises a coset leader of said coset; and,
an information sequence generator for generating an information sequence indicative of said compression code, and affixing said information sequence to said compressed sequence thereby to form an output sequence.

11. A lossless data sequence compressor according to claim 10, wherein said sequence producer is operable iteratively to produce said compressed sequence until a termination condition is reached, thereby producing a concluding compressed sequence and compression code.

12. A lossless data sequence compressor according to claim 11, wherein said sequence producer comprises a code generator for producing successive iterations of said compression code.

13. A lossless data sequence compressor according to claim 12, wherein said sequence producer further comprises an input segment encoder for selecting a segment of said input data sequence, and encoding said segment into a compressed segment by means of a current iteration of said dynamically generated compression code.

14. A lossless data sequence compressor according to claim 13, wherein said segment of said input data sequence comprises an entire input data sequence.

15. A lossless data sequence compressor according to claim 12, wherein said dynamically generated compression code comprises a time-varying convolutional code.

16. A lossless data sequence compressor according to claim 15, wherein said input segment encoder is operable to encode said input data segment by multiplying said input data segment by a transpose of a parity check matrix of said time-varying convolutional code.

17. A lossless data sequence compressor according to claim 15, wherein said code generator is operable to construct a compression code as a sequence of sub-codes.

18. A lossless data sequence compressor according to claim 17, wherein said code generator is operable to construct said compression code by dynamically selecting a sequence of sub-codes from a predetermined set of sub-codes.

19. A lossless data sequence compressor according to claim 18, wherein said sub-codes comprise convolutional codes.

20. A lossless data sequence compressor according to claim 19, wherein said input segment encoder comprises:
a segment divider for dividing said input data sequence into variable length sub-segments; and,
a segment compressor for compressing each of said sub-segments with an associated sub-code dynamically selected by said code generator for said sub-segment.

21. A lossless data sequence compressor according to claim 20, wherein said segment compressor comprises:
a transposer for transposing a parity check matrix of a sub-code associated with said sub-segment to form a transposed parity check matrix; and,
a multiplier for encoding each of said sub-segments by multiplying said sub-segment by a transposed parity check matrix of said associated sub-code.

22. A lossless data sequence compressor according to claim 20, wherein said input segment encoder comprises a sub-segment length adjustment.

23. A lossless data sequence compressor according to claim 22, wherein said code generator comprises code adjustment functionality for dynamically adjusting said compression code in accordance with said sub-segment length.

24. A lossless data sequence compressor according to claim 20, wherein said input segment encoder and said code generator are jointly operable to dynamically adjust said sub-segments and said sequence of sub-codes to fulfill at least one predetermined coding constraint.

25. A lossless data sequence compressor according to claim 22, wherein said input segment encoder is operable to restrict input sub-segment length to less than a predetermined length.

26. A lossless data sequence compressor according to claim 22, wherein said encoder is operable to restrict input sub-segment length to less than a predetermined length if a coding rate of said associated sub-code is less than a predetermined coding rate.

27. A lossless data sequence compressor according to claim 17, wherein said sequence producer further comprises a coset analyzer operable to identify a coset leader of a coset of said compression code and to compare said coset leader to said input data sequence, wherein said coset is determined by said compressed segment and said compression code.

28. A lossless data sequence compressor according to claim 27, wherein said coset analyzer comprises an error trellis generator for representing said coset as an error trellis, the error trellis having a path corresponding to each member of the coset.

29. A lossless data sequence compressor according to claim 28, wherein said error trellis generator is operable to generate said trellis as a concatenated sequence of error trellis modules dynamically selected from a predetermined set of error trellis modules.

30. A lossless data sequence compressor according to claim 29, wherein said error trellis generator is operable to determine the structure of said error trellis from said compressed segment and said compression code.

31. A lossless data sequence compressor according to claim 29, wherein said error trellis generator is operable to determine the structure of said error trellis from said compressed segment and from said sequence of sub-codes.

32. A lossless data sequence compressor according to claim 29, wherein said coset analyzer further comprises an error trellis searcher operable to search said error trellis for a coset leader.

33. A lossless data sequence compressor according to claim 32, wherein said error trellis searcher is operable to identify said coset leader by performing a search of said error trellis to detect a minimum Hamming weight path through said error trellis.

34. A lossless data sequence compressor according to claim 33, wherein said search is a Viterbi algorithm search.

35. A lossless data sequence compressor according to claim 32, wherein said coset analyzer further comprises a sequence comparator operable to perform a symbol by symbol comparison of said input segment with said coset leader, thereby to determine a symbol at which said input segment and said coset leader diverge.

36. A lossless data sequence compressor according to claim 35, wherein said input segment encoder and said code generator are jointly operable to dynamically adjust input data segment length and said compression code additionally based on information provided by said coset analyzer.

37. A lossless data sequence compressor according to claim 10, wherein said information sequence generator is operable to include in said information sequence an identification of the compression code utilized to generate said compressed sequence.

38. A lossless data sequence decompressor for decompressing a compressed sequence into an output sequence without loss of information, wherein said compressed sequence comprises a syndrome of a coset of a time-varying error correction code and an information sequence indicative of said time-varying error correction code, and wherein said decompressor comprises:
an information sequence separator, operable to separate said compressed sequence into said syndrome and said information sequence; and,
an expander operable to decompress said compressed sequence into said output sequence such that said output sequence equals a coset leader of said coset.

39. A lossless data sequence decompressor according to claim 38, wherein said expander further comprises an error trellis regenerator operable to represent said coset as a time-varying error trellis, the error trellis having a path corresponding to each member of the coset.

40. A lossless data sequence decompressor according to claim 39, wherein said error trellis regenerator is operable to generate said error trellis as a concatenated sequence of error trellis modules, and wherein each of said modules is dynamically selectable from a predetermined set of modules.

41. A lossless data sequence decompressor according to claim 40, wherein error trellis regenerator is operable to determine said sequence of error trellis modules from said syndrome and from said information sequence.

42. A lossless data sequence decompressor according to claim 39, wherein said expander further comprises an error trellis searcher operable to search said error trellis for a coset leader.

43. A lossless data sequence decompressor according to claim 42, wherein said error trellis searcher performs said search has a Viterbi algorithm search of said error trellis to detect a minimum Hamming weight path through said error trellis.

44. A communication device, comprising a first signal converter for converting a first data sequence into a first output sequence without loss of information utilizing a compression code, said compression code comprising a time-varying error correction code having cosets, each coset having a coset leader and syndrome, said first signal converter comprising:
a sequence producer for producing a compressed sequence comprising the syndrome of a coset of said compression correction code such that said first data sequence comprises a coset leader of said coset; and,
an information sequence generator for generating an information sequence indicative of said compression code, and affixing said information sequence to said compressed sequence to form a first output sequence.

45. A communication device according to claim 44, wherein said sequence producer is operable iteratively to produce said compressed sequence until a termination condition is reached, thereby producing a concluding compressed sequence and compression code.

46. A communication device according to claim 45, wherein said sequence producer comprises a code generator for producing successive iterations of said compression code.

47. A communication device according to claim 46, wherein said sequence producer further comprises an input segment encoder for selecting a segment of said input data sequence, and encoding said segment into a compressed segment by means of a current iteration of said dynamically generated compression code.

48. A communication device according to claim 47, wherein said segment of said input data sequence comprises an entire input data sequence.

49. A communication device according to claim 46, wherein said sequence producer further comprises a coset analyzer operable to identify a coset leader of a coset of said compression code, wherein said coset is determined by said compressed segment and said compression code.

50. A communication device according to claim 49, wherein said coset analyzer comprises an error trellis generator operable for forming said error trellis as a concatenated sequence of error trellis modules dynamically selectable from a predetermined set of modules.

51. A communication device according to claim 50, wherein error trellis generator is operable to determine said sequence of error trellis modules from said syndrome and from said information sequence.

52. A communication device according to claim 51, wherein said coset analyzer further comprises an error trellis searcher operable to search said error trellis for a coset leader.

53. A communication device according to claim 52, wherein said coset analyzer further comprises a comparator operable to perform a symbol by symbol comparison of said input segment with said coset leader, thereby to determine a symbol at which said first data segment and said coset leader diverge.

54. A communication device according to claim 49, wherein said information sequence generator is operable to include in said information sequence an identification of the compression code utilized to generate said compressed sequence.

55. A communication device according to claim 52, wherein said error trellis searcher identifies said coset leader by performing a Viterbi algorithm search of said error trellis to determine a minimum Hamming weight path through said error trellis.

56. A communication device according to claim 47, wherein said communication device further comprising a second signal converter for converting a second data sequence into a decompressed sequence without loss of information, wherein said second data sequence comprises a syndrome of a coset of a time-varying error correction code and an information sequence indicative of said time-varying error correction code, said second signal converter comprising:
an information sequence separator, operable to separate said second data sequence into said syndrome and said information sequence; and,
an expander operable to expand said compressed sequence into said decompressed sequence such that said decompressed sequence equals a coset leader of said coset.

57. A communication device according to claim 56, wherein said expander comprises an error trellis regenerator operable to represent said coset as a dynamically generated error trellis, the error trellis having a path corresponding to each member of the coset.

58. A communication device according to claim 57, wherein said error trellis regenerator is operable to construct said error trellis as a concatenated sequence of error trellis modules, said modules being dynamically selectable from a predetermined set of modules.

59. A communication device according to claim 58, wherein said error trellis regenerator is operable to determine said sequence of error trellis modules from said syndrome and said information sequence.

60. A communication device according to claim 56, wherein said expander further comprises an error trellis searcher operable to search said error trellis for a coset leader.

61. A communication device according to claim 60, wherein said error trellis searcher performs said search as a Viterbi algorithm search of said error trellis thereby to detect a minimum Hamming weight path through said error trellis.

62. A communication device according to claim 45, wherein said communication device comprises one of a group of devices comprising:
a router, a data switch, a data hub, a terminal for wireless communications, a terminal for wire communications, a personal computer, a cellular telephone handset, a mobile communication handset, and a personal digital assistant.

63. A communication device according to claim 56, wherein said communication device is any one of a group of devices comprising: a router, a data switch, a data hub, a terminal for wireless communication, a terminal for wire communication, a personal computer, a cellular telephone handset, a mobile communication handset, and a personal digital assistant.

64. A method for analyzing a coset of a time-varying error correction code for data communications, the time-varying error correction code having cosets, each coset having a coset leader and syndrome, comprising:
representing a coset of said code as a time-varying error trellis; and,
analyzing said coset to determine at least one property thereof.

65. A method for analyzing a coset of a time-varying error correction code according to claim 64, wherein determining a property thereof comprises identifying a coset leader of said coset.

66. A method for analyzing a coset of a time-varying error correction code according to claim 65, wherein identifying a coset leader of said coset comprises searching said error trellis for a minimum Hamming weight path through said error trellis.

67. A method for analyzing a coset of a time-varying error correction code according to claim 64, wherein determining a property thereof comprises determining whether a data sequence comprises a member of said coset.

68. A method for analyzing a coset of a time-varying error correction code according to claim 64, wherein said code comprises a convolutional code.

69. A method for analyzing a coset of a time-varying error correction code according to claim 64, wherein representing said error trellis comprises concatenating a sequence of error trellis modules, and wherein said modules are selected from a predetermined set of modules.

70. A method for analyzing a coset of a time-varying error correction code according to claim 69, further comprising determining said sequence of error trellis modules from said time-varying error correction code and from a syndrome sequence associated with said coset of said code.

71. A method for compressing an input data sequence into a compressed sequence without loss of information, comprising:
inputting an input data sequence;
generating a time-varying error correction code having said input data sequence as a coset leader of a coset of said code;
determining the syndrome of said coset; and,
forming an output sequence by affixing an information sequence indicative of said error-correction code to said syndrome.

72. A method for compressing an input data sequence into a compressed sequence without loss of information according to claim 71, wherein the step of generating a time-varying error correction code comprises dynamically selecting a sequence of sub-codes from a predetermined set of sub-codes.

73. A method for compressing an input data sequence into a compressed sequence without loss of information according to claim 72, wherein said sequence of sub-codes is determined from said input data sequence.

74. A method for compressing an input data sequence into a compressed sequence without loss of information, comprising:
inputting an input data sequence;
constructing an initial time-varying error correction code having cosets;
determining a parity check matrix for said code;
selecting a segment of said input data sequence;
performing an compression cycle to compress said segment of said data sequence by:
multiplying said segment of said input data sequence with a transpose of said parity check matrix to obtain a syndrome sequence;
representing a coset associated by said code with said syndrome sequence as an error trellis;
determining a coset leader of said coset;
comparing said coset leader to said input sequence;
if said coset leader and said segment of said input sequence are not identical, continuing said compression by:
updating said time-varying error correction code;
determining a parity check matrix for said code;
updating said segment of said input data sequence; and,
repeating said compression cycle to compress said segment of said input data sequence;
if said coset leader and said segment of input sequence are identical, continuing said compression by:
comparing the lengths of said coset leader and said input sequence;
if the lengths of said coset leader and said input sequence are not equal, continuing said compression by:
updating said time-varying error correction code;
determining a parity check matrix for said code;
extending said segment of said input data sequence; and,
repeating said compression cycle to compress said segment of said input data sequence;
if the lengths of said coset leader and said input sequence are equal, discontinuing said compression by:
forming an information sequence indicative of said time-varying error correction code;
forming a compressed sequence by affixing said information sequence to said syndrome sequence; and,
outputting said compressed sequence.

75. A method for compressing an input data sequence into a compressed sequence without loss of information according to claim 74, wherein said segment of said input data sequence comprises the entire input data sequence.

76. A method for compressing an input data sequence into a compressed sequence without loss of information according to claim 74, wherein said time-varying error correction code comprises a time-varying convolutional code.

77. A method for compressing an input data sequence into a compressed sequence without loss of information according to claim 76, wherein said convolutional code comprises a sequence of convolutional sub-codes, and wherein said sub-codes are selected from a predetermined set of sub-codes.

78. A method for compressing an input data sequence into a compressed sequence without loss of information according to claim 77, wherein constructing an initial time-varying error correction code comprises dynamically selecting an initial sequence of sub-codes from a predetermined set of sub-codes.

79. A method for compressing an input data sequence into a compressed sequence without loss of information according to claim 77, wherein updating said time-varying error correction code comprises cosets comprises dynamically reselecting said sequence of sub-codes.

80. A method for compressing an input data sequence into a compressed sequence without loss of information according to claim 77, wherein multiplying said segment of said input data sequence with a transpose of said parity check matrix comprises:
dividing said input data sequence into variable length sub-segments;
associating a sub-code with each of said sub-segments; and,
multiplying said input data segment by a transpose of a parity check matrix of the sub-code associated with said sub-segment.

81. A method for compressing an input data sequence into a compressed sequence without loss of information according to claim 80, further comprising ensuring that the length of each of said sub-segments does not exceed a predetermined size.

82. A method for compressing an input data sequence into a compressed sequence without loss of information according to claim 74, wherein determining a coset leader of said coset comprises searching said error trellis for a minimum Hamming weight path through said error trellis.

83. A method for compressing an input data sequence into a compressed sequence without loss of information according to claim 82, wherein said search is a Viterbi algorithm search.

84. A method for compressing an input data sequence into a compressed sequence without loss of information according to claim 74, wherein representing a coset associated by said code with said syndrome sequence as an error trellis comprises:
determining a sequence of error trellis modules selected from a predetermined set of modules, wherein said sequence of error trellis modules is determined from said time-varying error correction code and from said syndrome sequence; and,
forming said error trellis by concatenating said error trellis modules according to said determined sequence.

85. A method for compressing an input data sequence into a compressed sequence without loss of information, comprising:
inputting an input data sequence;
selecting an initial compression code having cosets;
selecting a segment of said input data sequence;
performing a compression cycle to compress said segment of said data sequence, by:
encoding said segment of said input data sequence with said compression code to form an encoded sequence;
analyzing a coset associated with said compression code by said compressed sequence to determine if said encoded sequence equals a coset leader of said coset;
if said segment of said input data sequence does not equal said coset leader, continuing said compression by:
reselecting a compression code;
reselecting a segment of said data sequence;
repeating said compression cycle;
if said segment of said input data sequence equals said coset leader, continuing said compression by:
comparing the lengths of said coset leader and said input sequence;
if the lengths of said coset leader and said input sequence are not equal, continuing said compression by:
extending said compression code;
extending said segment of said data sequence;
repeating said compression cycle;
if the lengths of said coset leader and said input sequence are equal, ending said compression by:
forming an information sequence indicative of said compression code;
forming a compressed sequence by affixing said information sequence to said encoded sequence; and,
outputting said compressed sequence.

86. A method for compressing an input data sequence into a compressed sequence without loss of information according to claim 85, wherein analyzing a coset associated with said compression code comprises:
representing said coset as an error trellis;
searching said error trellis to determine a coset leader; and, comparing said coset leader with said encoded sequence.

87. A method for compressing an input data sequence into a compressed sequence without loss of information according to claim 86, wherein searching said error trellis to determine a coset leader comprises performing a Viterbi algorithm search to identify a minimum Hamming weight path through said error trellis.

88. A method for compressing an input data sequence into a compressed sequence without loss of information according to claim 86, wherein representing said coset as an error trellis comprises:
determining a sequence of error trellis modules from said compression code and from said encoded sequence, wherein said modules are selected from a predetermined set of modules; and,
concatenating said error trellis modules according to said sequence.

89. A method for compressing an input data sequence into a compressed sequence without loss of information according to claim 85, wherein said compression code comprises a time-varying error correction code.

90. A method for compressing an input data sequence into a compressed sequence without loss of information according to claim 89, wherein said time-varying error correction code comprises a time-varying convolutional code.

91. A method for compressing an input data sequence into a compressed sequence without loss of information according to claim 90, wherein encoding said segment of said input data sequence comprises multiplying said segment by a transpose of a parity check matrix of said convolutional code.

92. A method for decompressing a compressed sequence without loss of information, by:
inputting said compressed sequence;
separating said compressed sequence into a syndrome and an information sequence;
analyzing a coset associated with said syndrome to determine a coset leader for said coset; and,
outputting said coset leader.

93. A method for decompressing a compressed sequence without loss of information according to claim 92, wherein analyzing a coset associated with said syndrome to determine a coset leader for said coset comprises:
representing said coset as a time-varying error trellis; and, searching said trellis to identify a Hamming weight path through said error trellis.

94. A method for decompressing a compressed sequence without loss of information according to claim 93, wherein representing said coset as a time-varying error trellis comprises:
determining a sequence of error trellis modules from said information sequence and said syndrome, wherein said modules are selected from a predetermined set of modules; and,
concatenating said error trellis modules according to said sequence.

95. A method for decompressing a compressed sequence without loss of information according to claim 93, wherein searching said trellis to identify a minimum Hamming weight path comprises performing a Viterbi algorithm search to identify said path.

96. A method for communicating data by transmitting and receiving data sequences, comprising converting a first data sequence into a compressed output data sequence without loss of information and transmitting said compressed sequence by:
inputting said first data sequence;
generating a time-varying error correction code having said first data sequence as a coset leader of a coset of said code;
determining the syndrome of said coset;
forming an information sequence indicative of said time-varying error-correction code;
forming a compressed sequence by affixing said information sequence to said syndrome; and,
transmitting said compressed sequence;
and further comprising receiving a second data sequence and converting said second data sequence into a decompressed sequence without loss of information by:
receiving said second data sequence;
separating said second data sequence into a syndrome and an information sequence;
representing a coset associated with said syndrome as a time-varying error trellis;
analyzing said error trellis to determine a coset leader for said coset; and,
setting said decompressed sequence equal to said coset leader.

97. A coset analyzer for use with trellis codes in data communications, the trellis code comprising cosets, each coset having a coset leader and syndrome, the analyzer comprising:
a coset representation unit for representing a coset of said code as a time-varying error trellis, the error trellis having a path corresponding to each member of the coset; and,
an error trellis searcher for searching said error trellis.

98. A coset analyzer for data communication according to claim 97, wherein said trellis code comprises a time-varying error correction code.

99. A coset analyzer for data communication according to claim 98, wherein said time-varying error correction code comprises a convolutional code.

100. A coset analyzer for data communication according to claim 98, wherein said time-varying error correction code comprises a block code.

101. A method for analyzing a coset of a trellis code for data communications, the trellis code having cosets, each coset having a coset leader and syndrome, the method comprising:
representing a coset of said code as a time-varying error trellis; and,
analyzing said coset to determine at least one property thereof.

102. A method for analyzing a coset of a trellis code for data communications according to claim 101, wherein said trellis code comprises a time-varying error correction code.

103. A method for analyzing a coset of a trellis code for data communications according to claim 102, wherein said time-varying error correction code comprises a convolutional code.

104. A method for analyzing a coset of a trellis code for data communications according to claim 102, wherein said time-varying error correction code comprises a block code.
